(19) United States
(12) Patent Application Publication
(10) Pub. No.: US 2022/0389319 A1
(43) Pub. Date: Dec. 8, 2022

(54) LIQUID CRYSTAL COMPOSITION, LIGHT ABSORPTION ANISOTROPIC FILM, LAMINATE, AND IMAGE DISPLAY DEVICE

(71) Applicant: FUJIFILM Corporation, Tokyo (JP)

(72) Inventors: Keigo SHIGA, Kanagawa (JP); Wataru HOSHINO, Kanagawa (JP); Hiroshi MATSUYAMA, Kanagawa (JP); Takashi YONEMOTO, Kanagawa (JP)

(73) Assignee: FUJIFILM Corporation, Tokyo (JP)

(21) Appl. No.: 17/871,322

(22) Filed: Jul. 22, 2022

Related U.S. Application Data
(63) Continuation of application No. PCT/JP2021/002473, filed on Jan. 25, 2021.

(30) Foreign Application Priority Data
Jan. 27, 2020 (JP) 2020-010763

(51) Int. Cl. C09K 19/38; C09K 19/60; G02B 5/30

(52) U.S. Cl. CPC C09K 19/3852; C09K 19/601; G02B 5/3016; G02F 1/133528

(57) ABSTRACT

Provided are a liquid crystal composition that is capable of forming a light absorption anisotropic film having a low reflectance, and a light absorption anisotropic film, a laminate, and an image display device, each of which is obtained using the liquid crystal composition. The liquid crystal composition contains a side-chain type high-molecular-weight liquid crystalline compound and a dichroic substance, in which the side-chain type high-molecular-weight liquid crystalline compound is a copolymer having a repeating unit M including a mesogenic group and a repeating unit F including a fluorine atom.

### CROSS-REFERENCE TO RELATED APPLICATIONS

This application is a Continuation of PCT International Application No. PCT/JP2021/002473 filed on Jan. 25, 2021, which claims priority under 35 U.S.C. § 119(a) to Japanese Patent Application No. 2020-010763 filed on Jan. 27, 2020. The above application is hereby expressly incorporated by reference, in its entirety, into the present application.

### BACKGROUND OF THE INVENTION

### 1. Field of the Invention

The present invention relates to a liquid crystal composition, a light absorption anisotropic film, a laminate, and an image display device.

### 2. Description of the Related Art

In the related art, in a case where an attenuation function, a polarization function, a scattering function, or a light shielding function, and the like of irradiation light including laser light or natural light were required in the related art, a device that operates by a different principle for each function has been used. Therefore, products corresponding to the functions have also been produced by different production steps for each of the functions.

For example, in a liquid crystal display (LCD), a linearly polarizing plate and a circularly polarizing plate are used to control luminosity and birefringence in the display. In addition, also in an organic light emitting diode (OLED), the circularly polarizing plate is used to prevent the reflection of external light.

In the related art, iodine has been widely used as a dichroic substance in these polarizing plates (polarizing elements), but polarizing elements using an organic coloring agent instead of iodine as the dichroic substance have also been studied.

For example, WO2017/154907A and WO2018/124198A disclose a light absorption anisotropic film formed by using a liquid crystal composition containing a high-molecular-weight liquid crystalline compound and a dichroic substance.

### SUMMARY OF THE INVENTION

The present inventors have conducted studies on the light absorption anisotropic film described in WO2017/154907A and WO2018/124198A. and have thus clarified that there is a room for improvement in the reflectance on a surface of the light absorption anisotropic film.

Therefore, an object of the present invention is to provide a liquid crystal composition capable of forming a light absorption anisotropic film having a low reflectance, and a light absorption anisotropic film, a laminate, and an image display device, each of which is obtained using the liquid crystal composition.

The present inventors have conducted intensive studies on the object, and as a result, they have thus found that a light absorption anisotropic film having a low reflectance can be formed by using a liquid crystal composition containing a side-chain type high-molecular-weight liquid crystalline compound having a repeating unit including a mesogenic group and a repeating unit including a fluorine atom, together with a dichroic substance, thereby leading to the present invention.

That is, the present inventors have found that the object can be accomplished by the following configurations.

[1] A liquid crystal composition comprising:

a side-chain type high-molecular-weight liquid crystalline compound; and

a dichroic substance,

in which the side-chain type high-molecular-weight liquid crystalline compound is a copolymer having a repeating unit M including a mesogenic group and a repeating unit F including a fluorine atom.

[2] The liquid crystal composition as described in [1],

in which the repeating unit M is a repeating unit represented by Formula (1),

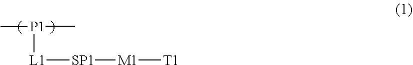

in Formula (1), P1 represents a main chain of the repeating unit, L1 represents a single bond or a divalent linking group, SP1 represents a spacer group, M1 represents a mesogenic group including 2 or more cyclic structures, and T1 represents a terminal group.

[3] The liquid crystal composition as described in [1] or [2],

in which the repeating unit F is a repeating unit represented by Formula (2),

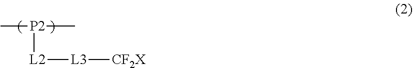

in Formula (2), P2 represents a main chain of the repeating unit, L2 represents a single bond or a divalent linking group, and L3 represents a divalent hydrocarbon group which may have a substituent, provided that one or more of —CH₂-'s constituting the divalent hydrocarbon group may be substituted with —O—, —S—, or —N(Q)-, Q represents a hydrogen atom or a substituent, and X represents a hydrogen atom or a fluorine atom.

[4] The liquid crystal composition as described in any one of [1] to [3],

in which the repeating unit F is a ting unit represented by Formula (3),

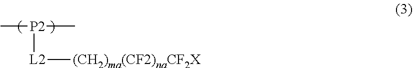

in Formula (3), P2 represents a main chain of the repeating unit, L2 represents a single bond or a divalent linking group, and ma and na each independently represent an integer of 0 to 19, provided that ma and na represent an integer of 0 to 19 in total, and X represents a hydrogen atom or a fluorine atom.

[5] The liquid crystal composition as described in any one of [1] to [4],

in which a content of the repeating unit F is 50% by mass or less with respect to a total mass of the side-chain type high-molecular-weight liquid crystalline compound.

[6] The liquid crystal composition as described in any one of [1] to [5],

in which a content of the side-chain type high-molecular-weight liquid crystalline compound is 0.5% by mass or more with respect to a total mass of a solid content of the liquid crystal composition.

[7] The liquid crystal composition as described in any one of [1] to [6], further comprising a liquid crystalline compound other than the side-chain type high-molecular-weight liquid crystalline compound.

[8] A side-chain type high-molecular-weight liquid crystalline compound comprising:

a repeating unit represented by Formula (1); and

a repeating unit represented by Formula (3),

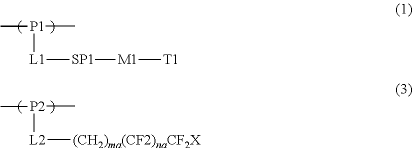

in Formula (1), P1 represents a main chain of the repeating unit, L1 represents a single bond or a divalent linking group, SP1 represents a spacer group, M1 represents a mesogenic group including 2 or more cyclic structures, and T1 represents a terminal group.

in Formula (3), P2 represents a main chain of the repeating unit, L2 represents a single bond or a divalent linking group, and ma and na each independently represent an integer of 0 to 19, provided that ma and na represent an integer of 0 to 19 in total, and X represents a hydrogen atom or a fluorine atom.

[9] A light absorption anisotropic film formed of the liquid crystal composition as described in any one of [1] to [7].

[10] A laminate comprising:

a substrate; and

the light absorption anisotropic film as described in [9] provided on the substrate.

[11] The laminate as described in [10], further comprising a λ/4 plate provided on the light absorption anisotropic film.

[12] An image display device comprising the light absorption anisotropic film as described in [9] or the laminate as described in [10] or [11].

As shown below, according to the present invention, it is possible to provide a liquid crystal composition capable of forming a light absorption anisotropic film having a low reflectance, and a light absorption anisotropic film, a laminate, and an image display device, each of which is obtained using the liquid crystal composition.

### DESCRIPTION OF THE PREFERRED EMBODIMENTS

Hereinafter, the present invention will be described in detail.

Description of configuration requirements described below may be made based on representative embodiments of the present invention, but the present invention is not limited to such embodiments.

Furthermore, in the present specification, a numerical range expressed using “to” means a range which includes the preceding and succeeding numerical values of “to” as a lower limit value and an upper limit value, respectively.

In addition, in the present specification, a (meth)acrylic acid is a general term for an “acrylic acid” and a “methacrylic acid”, and (meth)acryloyl is a general term for “acryloyl” and “methacrylic acid”.

[Liquid Crystal Composition]

The liquid crystal composition of an embodiment of the present invention is a liquid crystal composition containing a side-chain type high-molecular-weight liquid crystalline compound and a dichroic substance.

In addition, the side-chain type high-molecular-weight liquid crystalline compound contained in the liquid crystal composition of the embodiment of the present invention is a copolymer having a repeating unit M including a mesogenic group and a repeating unit F including a fluorine atom.

In the present invention, it is possible to form a light absorption anisotropic film having a low reflectance can be formed by using a liquid crystal composition containing a side-chain type high-molecular-weight liquid crystalline compound having a repeating unit M including a mesogenic group and a repeating unit F including a fluorine atom, together with a dichroic substance, as described above.

A reason therefor is not specifically clear, but is presumed to be as follows by the present inventors.

That is, it is considered that by configuring the side-chain type high-molecular-weight liquid crystalline compound to have the above-mentioned repeating unit M and repeating unit F, the light absorption anisotropic film can function as a low-refractive-index layer while maintaining the alignment properties, thus causing the reflectance to be reduced.

On the other hand, a light absorption anisotropic film containing a dichroic substance often causes reflection on an interface of a film. Therefore, the present inventors have presumed that by configuring the side-chain type high-molecular-weight liquid crystalline compound to have the above-mentioned repeating unit M and repeating unit F, the side-chain type high-molecular-weight liquid crystalline compound tends to be unevenly distributed in the vicinity of an interface of the light absorption anisotropic film, and a concentration of the dichroic substance existing in the vicinity of the interface is decreased, making it possible to suppress the reflection on an interface of the light absorption anisotropic film.

Hereinafter, the respective components of the liquid crystal composition of the embodiment of the present invention will be described in detail.

[Side-Chain Type High-Molecular-Weight Liquid Crystalline Compound]

As described above, the side-chain type high-molecular-weight liquid crystalline compound contained in the liquid crystal composition of the embodiment of the present invention is a copolymer having a repeating unit M including a mesogenic group and a repeating unit F including a fluorine atom.

Here, the side-chain type high-molecular-weight liquid crystalline compound means a high-molecular-weight liquid crystalline compound having a liquid crystal structure in a side chain.

In addition, the side-chain type high-molecular-weight liquid crystalline compound may be any polymer such as a block polymer, an alternate polymer, a random polymer, and a graft polymer.

Furthermore, the side-chain type high-molecular-weight liquid crystalline compound is hereinafter simply referred to as a “high-molecular-weight liquid crystalline compound” in some cases.

In addition, a substituent W used in the description of the high-molecular-weight liquid crystalline compound represents the following groups.

Specific examples of the substituent W include a halogen atom, an alkyl group having 1 to 20 carbon atoms, an alkyl halide group having 1 to 20 carbon atoms, a cycloalkyl group having 1 to 20 carbon atoms, an alkoxy group having 1 to 20 carbon atoms, an alkenyl group having 1 to 20 carbon atoms, an alkynyl group having 1 to 20 carbon atoms, an aryl group having 1 to 20 carbon atoms, a heterocyclic group (hetero ring group), a cyano group, a hydroxy group, a nitro group, a carboxy group, an aryloxy group, a silyloxy group, a heterocyclic oxy group, an acyloxy group, a carbamoyloxy group, an alkoxycarbonyloxy group, an aryloxycarbonyloxy group, and an amino group (including an anilino group; the same applies below), an ammonio group, an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imide group, a phosphino group, a phosphinyl group, a phosphinyloxy group, a phosphinylamino group, a phosphono group, a silyl group, a hydrazino group, an ureide group, a boronic acid group (—B(OH)₂), a phosphate group (—OPO(OH)₂), a sulfate group (—OSO₃H), and any of other substituents known in the art.

[Repeating Unit M]

The repeating unit M is a repeating unit including a mesogenic group.

Here, the mesogenic group is a group showing the main skeleton of a liquid crystal molecule that contributes to formation of a liquid crystal, the details are as described by M1 in Formula (1) which will be described later, and specific examples thereof are also the same.

For a reason that the alignment degree of a light absorption anisotropic film is improved, it is preferable that the repeating unit M is a repeating unit represented by Formula (1).

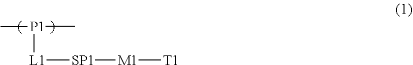

In Formula (1), P1 represents a main chain of the repeating unit, L1 represents a single bond or a divalent linking group, SP1 represents a spacer group, M1 represents a mesogenic group including 2 or more cyclic structures, and T1 represents a terminal group.

Specific examples of the main chain of the repeating unit represented by P1 in Formula (1) include groups represented by Formulae (P1-A) to (P1-D), and among these, the group represented by Formula (P1-A) is preferable from the viewpoints of a diversity of monomers used as raw materials and easy handling.

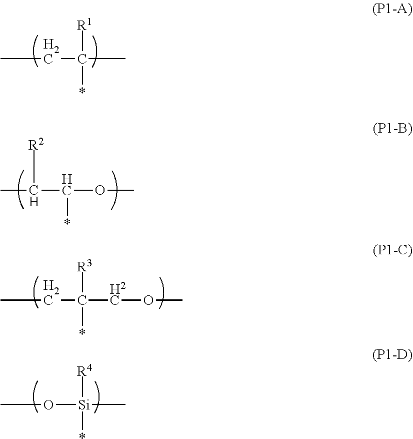

In Formulae (P1-A) to (P1-D), “*” represents a bonding position to L1 in Formula (1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The alkyl group may be a linear or branched alkyl group, or may be an alkyl group (cycloalkyl group) having a cyclic structure. In addition, the number of carbon atoms in the alkyl group is preferably 1 to 5.

The group represented by Formula (P1-A) is preferably one unit of a partial structure of a poly(meth)acrylic acid ester obtained by polymerization of a (meth)acrylic acid ester.

The group represented by Formula (P1-B) is preferably an ethylene glycol unit formed by ring-opening polymerization of an epoxy group of a compound having the epoxy group.

The group represented by Formula (P1-C) is preferably a propylene glycol unit formed by ring-opening polymerization of an oxetane group of a compound having the oxetane group.

The group represented by Formula (P1-D) is preferably a siloxane unit of a polysiloxane obtained by polycondensation of a compound having at least one group of an alkoxysilyl group or a silanol group. Here, examples of the compound having at least one group of an alkoxysilyl group or a silanol group include a compound having a group represented by a formula of SiR¹⁴(OR¹⁵)₂—. In the formula, R¹⁴ has the same definition as R¹⁴ in (P1-D), and a plurality of R's each independently represent a hydrogen atom or an alkyl group having 1 to 10 carbon atoms.

In Formula (1), L1 is a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom, or an alkyl group having 1 to 6 carbon atoms, which may have a substituent (for example, the above-mentioned substituent W).

In a case where P1 is the group represented by Formula (P1-A), it is preferable that L1 is a group represented by —C(O)O— for a reason that the alignment degree of a light absorption anisotropic film is improved.

In a case where P1 is the group represented by each of Formulae (P1-B) to (P1-D), it is preferable that L1 is the single bond for a reason that the alignment degree of a light absorption anisotropic film is improved.

For reasons of easy exhibition of liquid crystallinity, availability of a raw material, and the like, it is preferable that the spacer group represented by SP1 in Formula (1) includes at least one structure selected from the group consisting of an oxyethylene structure, an oxypropylene structure, a polysiloxane structure, and an alkylene fluoride structure.

Here, the oxyethylene structure represented by SP1 is preferably a group represented by *—(CH₂—CH₂O)ₙ₁—*. In the formula, n1 represents an integer of 1 to 20, and * represents a bonding position to L1 or M1 in Formula (1). For a reason that the alignment degree of a light absorption anisotropic film is improved, n1 is preferably an integer of 2 to 10, more preferably an integer of 2 to 4, and most preferably 3.

In addition, for a reason that the alignment degree of a light absorption anisotropic film is improved, it is preferable that the oxypropylene structure represented by SP1 is a group represented by *—(CH(CH₃)—CH₂O)ₙ₂—*. In the formula, n2 represents an integer of 1 to 3, and * represents a bonding position to L1 or M1.

In addition, for a reason that the alignment degree of a light absorption anisotropic film is improved, it is preferable that the polysiloxane structure represented by SP1 is a group represented by *—(Si(CH₃)₂—O)ₙ₃—*. In the formula, n3 represents an integer of 6 to 10, and * represents a bonding position to L1 or M1.

In addition, for a reason that the alignment degree of a light absorption anisotropic film is improved, it is preferable that the alkylene fluoride structure represented by SP1 is a group represented by *—(CF₂—CF₂)ₙ₄—*. In the formula, n4 represents an integer of 6 to 10, and * represents a bonding position to L1 or M1.

The mesogenic group represented by M1 in Formula (1) is a group representing a main skeleton of a liquid crystal molecule which contributes to liquid crystal formation. The liquid crystal molecule exhibits liquid crystallinity which is an intermediate state (mesophase) between a crystalline state and an isotropic liquid state. The mesogenic group is not particularly limited, and reference can be made to, for example, “Flussige Kristalle in Tabellen II” (VEB Deutsche Verlag fur Grundstoff Industrie, Leipzig, published in 1984), particularly the descriptions on pages 7 to 16, and Editorial committee of Liquid Crystal Handbook, liquid crystal handbook (Maruzen Publishing Co., Ltd., published in 2000), particularly the descriptions in Chapter 3.

As the mesogenic group, for example, a group having at least one kind of cyclic structure selected from the group consisting of an aromatic hydrocarbon group, a heterocyclic group, and an alicyclic group is preferable.

For a reason that the alignment degree of a light absorption anisotropic film is improved, the mesogenic group preferably has aromatic hydrocarbon groups, more preferably has two to four aromatic hydrocarbon groups, and still more preferably has three aromatic hydrocarbon groups.

As the mesogenic group, a group represented by Formula (M1-A) or Formula (M1-B) is preferable, and the group represented by Formula (M1-B) is more preferable from the viewpoints of exhibition of liquid crystallinity, adjustment of a liquid crystal phase transition temperature, availability of a raw material, and synthesis suitability, and for a reason that the alignment degree of a light absorption anisotropic film is improved.

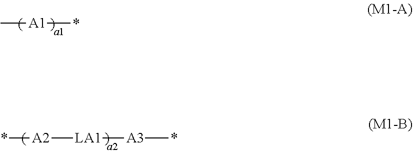

In Formula (M1-A), A1 is a divalent group selected from the group consisting of an aromatic hydrocarbon group, a heterocyclic group, and an alicyclic group. These groups may be substituted with an alkyl group, an alkyl fluoride group, an alkoxy group, or a substituent (for example, the above-mentioned substituent W).

The divalent group represented by A1 is preferably a 4- to 6-membered ring. In addition, the divalent group represented by A1 may be either a monocycle or a fused ring.

* represents a bonding position to SP1 or T1.

Examples of the divalent aromatic hydrocarbon group represented by A1 include a phenylene group, a naphthylene group, a fluorene-diyl group, an anthracene-diyl group, and a tetracene-diyl group, and from the viewpoint of a diversity of design of a mesogenic skeleton, availability of a raw material, or the like, a phenylene group or a naphthylene group is preferable and a phenylene group is more preferable.

The divalent heterocyclic group represented by A1 may be either aromatic or non-aromatic, but is preferably a divalent aromatic heterocyclic group from the viewpoint that the alignment degree is further improved.

Examples of atoms which constitute the divalent aromatic heterocyclic group and are other than carbon include a nitrogen atom, a sulfur atom, and an oxygen atom. In a case where the aromatic heterocyclic group has a plurality of atoms which constitute a ring and are other than carbon, these atoms may be the same as or different from each other.

Specific examples of the divalent aromatic heterocyclic group include a pyridylene group (pyridine-diyl group), a pyridazine-diyl group, an imidazole-diyl group, thienylene (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 is 2 or more, a plurality of A1's may be the same as or different from each other.

In Formula (M1-B), A2 and A3 are each independently a divalent group selected from the group consisting of an aromatic hydrocarbon group, a heterocyclic group, and an alicyclic group. Specific examples and suitable aspects of A2 and A3 are the same as those of A1 in Formula (M1-A), and thus descriptions thereof will be omitted.

In Formula (M1-B), a2 represents an integer of 1 to 10, and in a case where a2 is 2 or more, a plurality of A2's may be the same as or different from each other, a plurality of A3's may be the same as or different from each other, and a plurality of LA1's may be the same as or different from each other. For a reason that the alignment degree of a light absorption anisotropic film is improved, a2 is preferably an integer of 2 or more, and more preferably 2.

In Formula (M1-B), in a case where a2 is 1, LA1 is a divalent linking group. In a case where a2 is 2 or more, the plurality of LA1's are each independently a single bond or a divalent linking group, and at least one among the plurality of LA1's is a divalent linking group. In a case where a2 is 2, it is preferable that one of two LA1's is the divalent linking group and the other is the single bond for a reason that the alignment degree of a light absorption anisotropic film is improved.

Examples of the divalent linking group represented by LA1 in Formula (M1-B) include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)—N—N—C(Z′)— (Z, Z′, and Z″ independently represent hydrogen, a C1 to C4 alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among those, for a reason that the alignment degree of a light absorption anisotropic film is improved, —C(O)O— is preferable. LA1 may be a group obtained by combining two or more of these groups.

Specific examples of M1 include the following structures. Moreover, in the following specific examples, “Ac” represents an acetyl group.

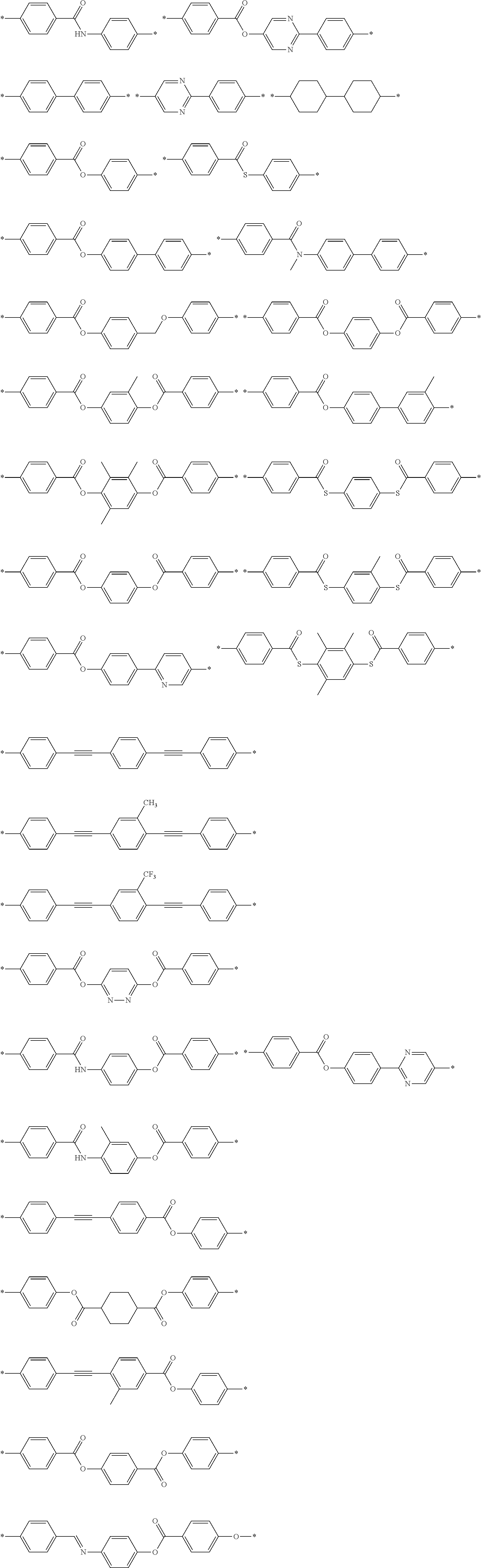

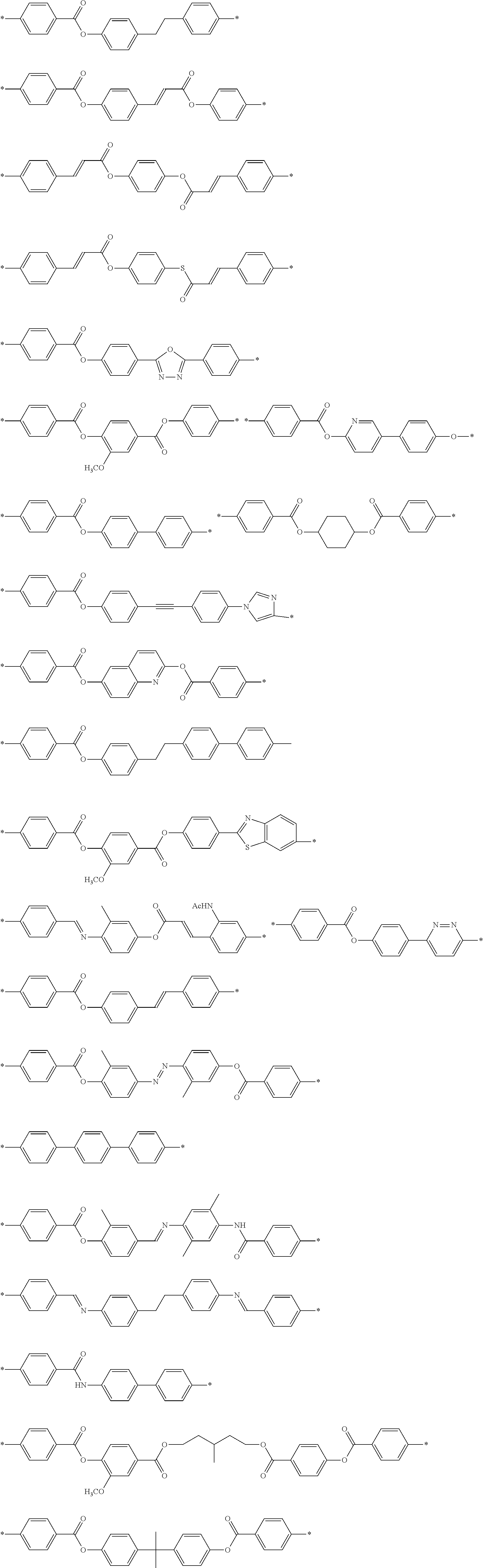

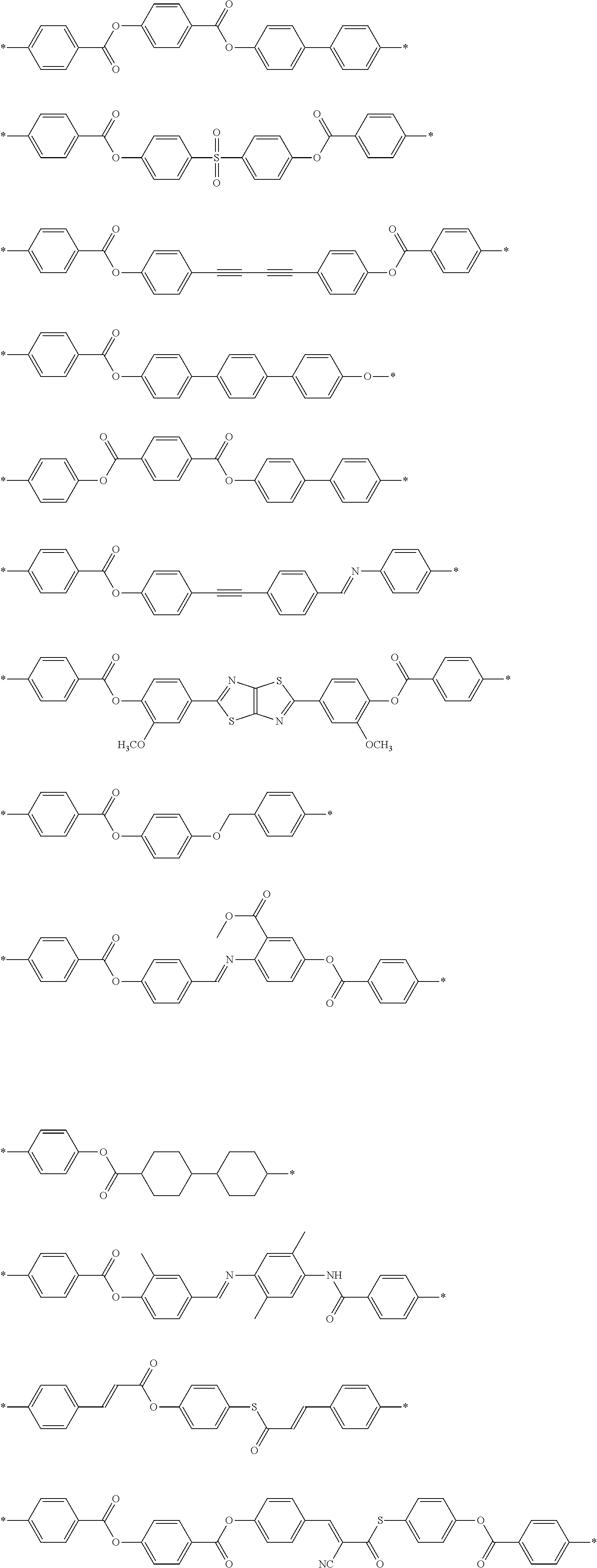

Examples of the terminal group represented by T1 in Formula (1) include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group (ROC(O)—: R is an alkyl group) having 1 to 10 carbon atoms, an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to 10 carbon atoms, and a (meth)acryloyloxy group-containing group. Examples of the (meth)acryloyloxy group-containing group include a group represented by -L-A (L represents a single bond or a linking group, specific examples of the linking group are the same as those of L1 and SP1 described above, and A represents a (meth)acryloyloxy group).

For a reason that the alignment degree of a light absorption anisotropic film is improved, T1 is preferably an alkoxy group having 1 to 10 carbon atoms, more preferably an alkoxy group having 1 to 5 carbon atoms, and still more preferably a methoxy group. These terminal groups may be further substituted with these groups or the polymerizable group described in JP2010-244038A.

For a reason that the alignment degree of a light absorption anisotropic film is improved, the number of atoms in the main chain of T1 is preferably 1 to 20, more preferably 1 to 15, still more preferably 1 to 10, and particularly preferably 1 to 7. In a case where the number of atoms in the main chain of T1 is 20 or less, the alignment degree of a light absorption anisotropic film is improved. Here, the “main chain” in T1 means the longest molecular chain bonded to M1, and the number of hydrogen atoms is not counted as the number of atoms in the main chain of T1. For example, in a case where T1 is an n-butyl group, the number of atoms in the main chain is 4, and in a case where T1 is a sec-butyl group, the number of atoms in the main chain is 3.

Specific examples of the repeating unit M include repeating units represented by the following structural formulae.

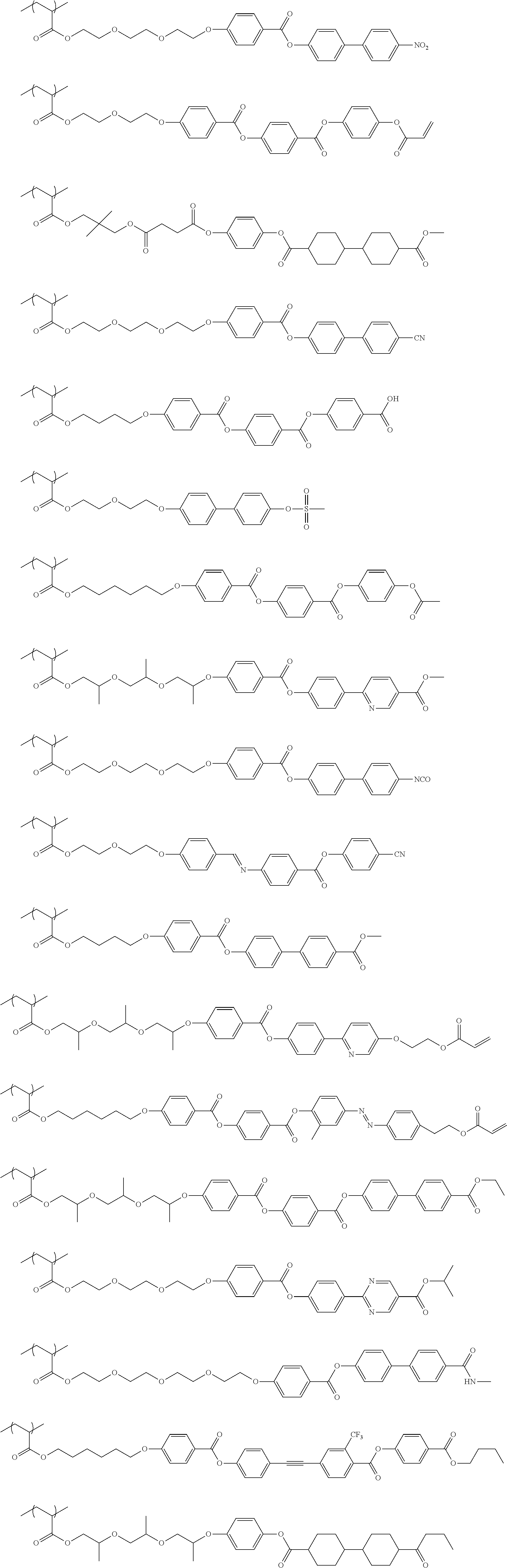

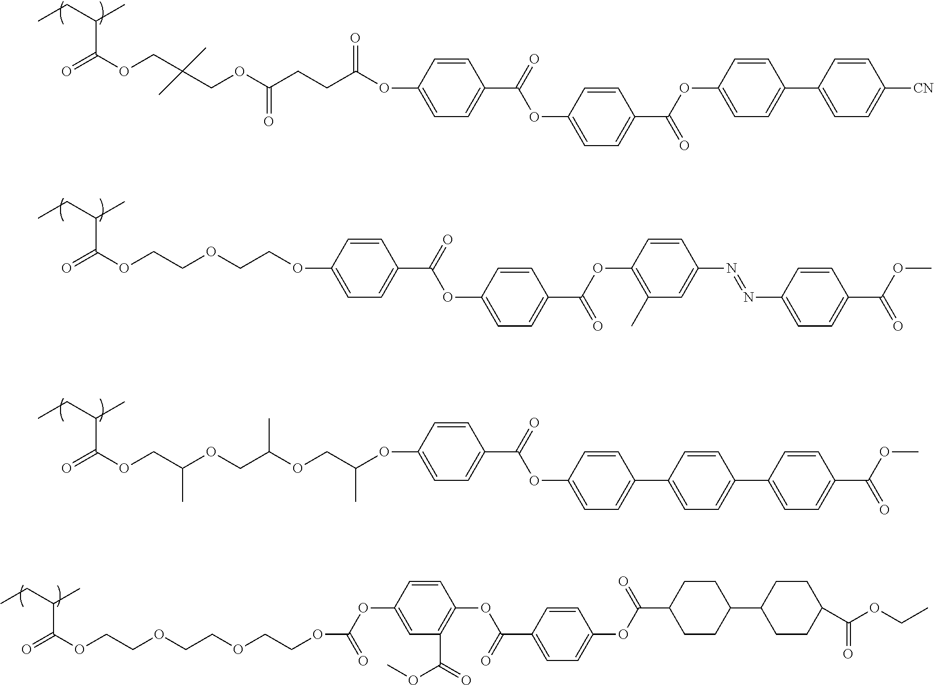

A content of the repeating unit M is preferably 25% to 99% by mass, and more preferably 50% to 98% by mass with respect to a total mass (100% by mass) of the high-molecular-weight liquid crystalline compound.

In the present invention, the content of each repeating unit included in the high-molecular-weight liquid crystalline compound is a value calculated based on a molar ratio of the respective repeating units in the polymer measured using a nuclear magnetic resonance (NMR) analyzer.

The high-molecular-weight liquid crystalline compound may include only one kind or two or more kinds of the repeating units M. In a case where the high-molecular-weight liquid crystalline compound includes two or more kinds of repeating units M, there are advantages such as improvement in a solubility of the high-molecular-weight liquid crystalline compound in a solvent and easy adjustment of the liquid crystal phase transition temperature. In a case where the two or more kinds of repeating units M are included, a total amount thereof is preferably in the range.

In a case where the high-molecular-weight liquid crystalline compound includes two kinds of repeating units M, for a reason that the alignment degree of a light absorption anisotropic film is improved, it is preferable that the terminal group represented by T1 is an alkoxy group in one repeating unit (repeating unit A) and the terminal group represented by T1 is a group other than an alkoxy group in the other repeating unit (repeating unit B).

For a reason that the alignment degree of a light absorption anisotropic film is improved, the terminal group represented by T1 in the repeating unit B is preferably an alkoxycarbonyl group, a cyano group, or a (meth)acryloyloxy group-containing group, and more preferably an alkoxycarbonyl group or a cyano group.

For a reason that the alignment degree of a light absorption anisotropic film is improved, a proportion (A/B) of the content of the repeating unit A in the high-molecular-weight liquid crystalline compound to the content of the repeating unit B in the high-molecular-weight liquid crystalline compound is preferably 50/50 to 95/5, more preferably 60/40 to 93/7, and still more preferably 70/30 to 90/10.

[Repeating Unit F]

The repeating unit F is a repeating unit including a fluorine atom.

Since the reflectance of the light absorption anisotropic film is further reduced, it is preferable that the repeating unit F is a repeating unit represented by Formula (2), and it is more preferable that the repeating unit F is a repeating unit represented by Formula (3).

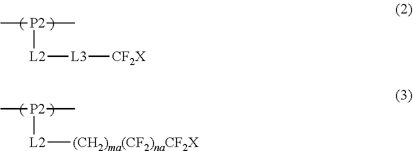

In Formula (2), P2 represents a main chain of the repeating unit, L2 represents a single bond or a divalent linking group, and L3 represents a divalent hydrocarbon group which may have a substituent. It should be noted that one or more of —CH₂—'s constituting the divalent hydrocarbon group may be substituted with —O—, —S—, or —N(Q)-. Q represents a hydrogen atom or a substituent. X represents a hydrogen atom or a fluorine atom.

In Formula (3), P2 represents a main chain of the repeating unit, L2 represents a single bond or a divalent linking group, and ma and na each independently represent an integer of 0 to 19. It should be noted that ma and na represent an integer of 0 to 19 in total. X represents a hydrogen atom or a fluorine atom.

In Formulae (2) and (3), specific examples of the main chain of the repeating unit represented by P2 are the same as those of P1 in Formula (1), suitable aspects are also the same, and descriptions thereof will be omitted.

In Formulae (2) and (3), specific examples of the divalent linking group represented by L2 are the same as those of L1 in Formula (1), suitable aspects are also the same, and descriptions thereof will be omitted.

In Formula (3), the divalent hydrocarbon group which may have a substituent, represented by U, will be described.

Examples of the substituent include the above-mentioned substituents W, and among those, the alkyl halide group is preferable.

In addition, examples of the divalent hydrocarbon group include a linear alkylene group having 1 to 18 carbon atoms, a branched or cyclic alkylene group having 3 to 18 carbon atoms, and an arylene group having 6 to 12 carbon atoms, which may have a substituent. Among these, the linear alkylene group having 1 to 18 carbon atoms is preferable, a linear alkylene group having 1 to 12 carbon atoms is more preferable, a linear alkylene group having 1 to 6 carbon atoms is more preferable, and a linear alkylene group having 1 to 4 carbon atoms is particularly preferable.

In Formula (3), ma and na each independently represent an integer of 0 to 19, but ma is preferably an integer of 1 to 8, and more preferably an integer of 1 to 5. In addition, na is preferably an integer of 1 to 15, more preferably an integer of 1 to 12, still more preferably an integer of 2 to 10, and most preferably an integer of 5 to 7.

In Formulae (2) and (3), X represents a hydrogen atom or a fluorine atom, and is preferably a fluorine atom.

Specific examples of the monomer forming the repeating unit represented by Formula (2) include hexafluoroisopropylacrylamide (HFIPA).

Specific examples of a monomer forming the repeating unit represented by Formula (3) include 2,2,2-trifluoroethyl (meth)acrylate, 2,2,3,3,3-pentafluoropropyl (meth)acrylate, 2-(perfluorobutyl)ethyl (meth)acrylate, 2-(perfluorohexyl)ethyl (meth)acrylate, 2-(perfluorooctyl)ethyl (meth)acrylate, 2-(perfluorodecyl)ethyl (meth)acrylate, 2-(perfluoro-3-methylbutyl)ethyl (meth)acrylate, 2-(perfluoro-5-methylhexyl)ethyl (meth)acrylate, 2-(perfluoro-7-methyloctyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H,1H,9H-hexadecafluorononyl (meth)acrylate, 1H-1-(trifluoromethyl)trifluoroethyl (meth)acrylate, 1H,1H,3H-hexafluorobutyl (meth)acrylate, 3-perfluorobutyl-2-hydroxypropyl (meth)acrylate, 3-perfluorohexyl-2-hydroxypropyl (meth)acrylate, 3-perfluorooctyl-2-hydroxypropyl (meth)acrylate, 3-(perfluoro-3-methylbutyl)-2-hydroxypropyl (meth)acrylate, 3-(perfluoro-5-methylhexyl)-2-hydroxypropyl (meth)acrylate, and 3-(perfluoro-7-methyloctyl)-2-hydroxypropyl (meth)acrylate.

For a reason that the reflectance of a light absorption anisotropic film is further reduced while maintaining good liquid crystallinity, a content of the repeating unit F is preferably 50% by mass or less, more preferably 40% by mass or less, and still more preferably 2% to 40% by mass with respect to the total mass of the side-chain type high-molecular-weight liquid crystalline compound.

A weight-average molecular weight (Mw) of the high-molecular-weight liquid crystalline compound is preferably 1,000 to 500,000 and more preferably 2,000 to 300,000. In a case where the Mw of the high-molecular-weight liquid crystalline compound is in the range, it is easier to handle the high-molecular-weight liquid crystalline compound.

In particular, from the viewpoint of suppression of cracks during application, the weight-average molecular weight (Mw) of the high-molecular-weight liquid crystalline compound is preferably 10,000 or more, and more preferably 10,000 to 300,000.

Here, the weight-average molecular weight and the number-average molecular weight in the present invention are values measured by a gel permeation chromatography (GPC) method.
Solvent (eluent): N-Methylpyrrolidone
Device name: TOSOH HLC-8220GPC
Column: Three columns of TOSOH TSKgel Super AWM-H (6 mm×15 cm) linked to each other are used
Column temperature: 25° C.
Sample concentration: 0.1% by mass
Flow rate: 0.35 mL/min
Calibration curve: Calibration curve obtained from seven samples of TSK standard polystyrene Mw of 2,800,000 to 1,050 (Mw/MN=1.03 to 1.06) manufactured by Tosoh Corporation is used

The liquid crystallinity of the high-molecular-weight liquid crystalline compound may exhibit either a nematic property or a smectic property, but preferably exhibits at least the nematic property.

A temperature range exhibiting the nematic phase is preferably room temperature (23° C.) to 450° C., and more preferably 50° C. to 400° C. from the viewpoint of handleability and manufacturing suitability.

In the present invention, for a reason that the alignment degree of a light absorption anisotropic film is improved, a content of the high-molecular-weight liquid crystalline compound is preferably 0.5% by mass or more, more preferably 1% by mass or more, still more preferably 1% to 75% by mass, and particularly preferably 7% to 75% by mass with respect to the total mass of the solid content of the liquid crystal composition.

[Dichroic Substance]

The dichroic substance contained in the liquid crystal composition of the embodiment of the present invention is not particularly limited, and is a visible light absorption substance (dichroic coloring agent), a luminescent substance (a fluorescent substance, a phosphorescent substance), an ultraviolet absorption substance, an infrared absorption substance, a nonlinear optical substance, a carbon nanotube, and an inorganic substance (for example, a quantum rod), and dichroic substances (dichroic coloring agents) known in the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, and the like.

In the present invention, two or more dichroic substances may be used in combination, and for example, from the viewpoint of bringing a light absorption anisotropic film closer to black, it is preferable to use at least one coloring agent compound having a maximum absorption wavelength in the wavelength range of 370 to 550 nm and at least one coloring agent compound having a maximum absorption wavelength in the wavelength range of 500 to 700 nm in combination.

In the present invention, it is preferable that the dichroic substance has a crosslinkable group for a reason that the pressing resistance is good.

Specific examples of the crosslinkable group include a (meth)acryloyl group, an epoxy group, an oxetanyl group, and a styryl group, and among these, the (meth)acryloyl group is preferable.

A content of the dichroic substance is preferably 1% to 50% by mass, more preferably 3% to 45% by mass, and still more preferably 5% to 40% by mass with respect to the total mass of the solid content of the liquid crystal composition.

Furthermore, in a case where the liquid crystal composition of the embodiment of the present invention includes two or more kinds of dichroic substances, a total amount thereof is preferably within the range.

[Liquid Crystalline Compound]

For a reason that the alignment degree of a light absorption anisotropic film is improved, it is preferable that the liquid crystal composition of the embodiment of the present invention contains a liquid crystalline compound (hereinafter also simply referred to as “another liquid crystalline compound”) other than the above-mentioned side-chain type high-molecular-weight liquid crystalline compound.

As such another liquid crystalline compound, both of a low-molecular-weight liquid crystalline compound and a high-molecular-weight liquid crystalline compound can be used.

Here, the “low-molecular-weight liquid crystalline compound” refers to a liquid crystalline compound having no repeating unit in the chemical structure.

In addition, the “high-molecular-weight liquid crystalline compound” refers to a liquid crystalline compound having a repeating unit in the chemical structure.

Examples of the low-molecular-weight liquid crystalline compound include the liquid crystalline compounds described in JP2013-228706A.

Examples of the high-molecular-weight liquid crystalline compound include the thermotropic liquid crystalline polymers described in JP2011-237513A. In addition, the high-molecular-weight liquid crystalline compound may have a crosslinkable group (for example, an acryloyl group and a methacryloyl group) at the terminal.

Such another liquid crystalline compound may be used alone or in combination of two or more kinds thereof.

In addition, as such another liquid crystalline compound, a difference (Δ log P) in the log P value from the above-mentioned side-chain type high-molecular-weight liquid crystalline compound calculated by the following equation is preferably −5.0 to 5.0, more preferably −4.0 to 4.0, still more preferably −3.5 to 2.5, and particularly preferably −3.2 to 2.2. By using such a liquid crystalline compound, the above-mentioned side-chain type high-molecular-weight liquid crystalline compound and a general liquid crystal compound do not undergo phase separation, and are likely to be unevenly distributed in the vicinity of an interface in the light absorption anisotropic film, and thus, the effects of the invention are easily expressed.

Δ log P=(log P value of side-chain type high-molecular-weight liquid crystal)−(log P value of liquid crystalline compound) (Equation)

Here, the log P value is an index expressing hydrophilicity and hydrophobicity of a chemical structure, and is sometimes referred to as a hydrophilicity/hydrophobicity parameter. The log P value can be calculated using software such as ChemBioDraw Ultra or HSPiP (Ver. 4.1.07). In addition, the log P value can be experimentally determined by the method in OECD Guidelines for the Testing of Chemicals, Sections 1, Test No. 117, and the like. In the present invention, a value calculated by inputting a structural formula of a compound into HSPiP (Ver. 4.1.07) is adopted as the log P value unless otherwise specified.

In a case where the liquid crystal composition of the embodiment of the present invention contains another liquid crystalline compound, a content of such another liquid crystalline compound is preferably 1% to 98% by mass, more preferably 3% to 95% by mass, and still more preferably 5% to 90% by mass with respect to the total mass of the solid content of the liquid crystal composition.

[Polymerization Initiator]

The liquid crystal composition of the embodiment of the present invention preferably contains a polymerization initiator.

The polymerization initiator is not particularly limited, but is preferably a photosensitive compound, that is, a photopolymerization initiator.

As the photopolymerization initiator, various kinds of compounds can be used with no particular limitation. Examples of the photopolymerization initiator include the α-carbonyl compound (each of the specifications of U.S. Pat. Nos. 2,367,661A and 2,367,670A), the acyloin ether (the specification of U.S. Pat. No. 2,448,828A), the α-hydrocarbon-substituted aromatic acyloin compound (the specification of U.S. Pat. No. 2,722,512A), the polynuclear quinone compound (each of the specifications of U.S. Pat. Nos. 3,046,127A and 2,951,758A), the combination of a triarylimidazole dimer and p-aminophenyl ketone (the specification of U.S. Pat. No. 3,549,367A), the acridine and phenazine compounds (JP1985-105667A (JP-S60-105667A) and the specification of U.S. Pat. No. 4,239,850A), the oxadiazole compound (the specification of U.S. Pat. No. 4,212,970A), and the acyl phosphine oxide compounds (JP1988-40799B (JP-S63-40799B), JP1993-29234B (JP-H05-29234B), JP1998-95788A (JP-H10-95788A), and JP1998-29997A (JP-H10-29997A)).

As such a photopolymerization initiator, a commercially available product can also be used, and examples thereof include IRGACURE 184, 907, 369, 651, and 819, OXE-01, and OXE-02, all manufactured by BASF.

In a case where the liquid crystal composition of the embodiment of the present invention contains a polymerization initiator, a content of the polymerization initiator is preferably 0.01 to 30 parts by mass, and more preferably 0.1 to 15 parts by mass with respect to 100 parts by mass of a total amount of the side-chain type high-molecular-weight liquid crystalline compound and the dichroic substance in the liquid crystal composition. In a case where the content of the polymerization initiator is 0.01 parts by mass or more, the durability of the light absorption anisotropic film is good, whereas in a case where the content of the polymerization initiator is 30 parts by mass or less, the alignment of the light absorption anisotropic film is good.

[Solvent]

The liquid crystal composition of the embodiment of the present invention preferably contains a solvent from the viewpoint of workability and the like.

Examples of the solvent include organic solvents such as ketones (for example, acetone, 2-butanone, methyl isobutyl ketone, cyclopentanone, and cyclohexanone), ethers (for example, dioxane, tetrahydrofuran, 2-methyltetrahydrofuran, cyclopentylmethyl ether, tetrahydropyran, and dioxolane), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane, dichloroethane, dichlorobenzene, and chlorotoluene), esters (for example, methyl acetate, ethyl acetate, butyl acetate, and ethyl lactate), alcohols (for example, ethanol, isopropanol, butanol, cyclohexanol, isopentyl alcohol, neopentyl alcohol, diacetone alcohol, and benzyl alcohol), cellosolves (for example, methyl cellosolve, ethyl cellosolve, and 1,2-dimethoxyethane), cellosolve acetates, sulfoxides (for example, dimethyl sulfoxide), amides (for example, dimethylformamide, dimethylacetamide, N-methylpyrrolidone, and N-ethylpyrrolidone), and heterocyclic compounds (for example, pyridine), and water. These solvents may be used alone or in combination of two or more kinds thereof.

Among these solvents, ketones (in particular, cyclopentanone and cyclohexanone), ethers (in particular, tetrahydrofuran, cyclopentylmethyl ether, tetrahydropyran, and dioxolane), and amides (in particular, dimethylformamide, dimethylacetamide, N-methylpyrrolidone, and N-ethylpyrrolidone) are preferable from the viewpoint of utilizing the effect of excellent solubility.

In a case where the liquid crystal composition of the embodiment of the present invention contains a solvent, a content of the solvent is preferably 80% to 99% by mass, more preferably 83% to 98% by mass, and particularly preferably 85% to 96% by mass with respect to the total mass of the solid content of the liquid crystal composition.

[Interface Modifier]

The liquid crystal composition of the embodiment of the present invention preferably contains an interface modifier. By incorporating the interface modifier into the liquid crystal composition, the smoothness of the coating surface is improved, the alignment degree is improved, and the improvement of the in-plane uniformity through suppression of cissing and unevenness is anticipated.

As the interface modifier, an interface modifier having a liquid crystalline compound placed horizontal on the coated surface is preferable, and the compounds (horizontal alignment agents) described in paragraphs [0253] to [0293] of JP2011-237513A can be used. In addition, the fluorine (meth)acrylate-based polymers described in [0018] to [0043] of JP2007-272185A, and the like can also be used. As the interface modifier, compounds other than those may be used.

In a case where the liquid crystal composition of the embodiment of the present invention contains an interface modifier, a content of the interface modifier is preferably 0.001 to 5 parts by mass, and more preferably 0.01 to 3 parts by mass with respect to 100 parts by mass of a total amount of the side-chain type high-molecular-weight liquid crystalline compound and the dichroic substance in the liquid crystal composition.

[Side-Chain Type High-Molecular-Weight Liquid Crystalline Compound]

The side-chain type high-molecular-weight liquid crystalline compound of the embodiment of the present invention is a side-chain type high-molecular-weight liquid crystalline compound having the repeating unit represented by Formula (1) and the repeating unit represented by Formula (3).

[Light Absorption Anisotropic Film]

The light absorption anisotropic film of an embodiment of the present invention is a light absorption anisotropic film formed using the above-mentioned liquid crystal composition of the embodiment of the present invention.

As an example of a method for producing the light absorption anisotropic film of the embodiment of the present invention include a method including a step of applying the liquid crystal composition onto a substrate to form a coating film (hereinafter also referred to as a “coating film forming step”) and a step of aligning the dichroic substance included in the coating film (hereinafter also referred to as an “aligning step”) in this order can be cited.

Hereinafter, the respective steps of the production method for manufacturing the light absorption anisotropic film of the embodiment of the present invention will be described.

[Coating Film Forming Step]

The coating film forming step is a step of applying the liquid crystal composition onto a substrate to form a coating film.

It is easier to apply a liquid crystal composition onto the substrate by using a liquid crystal composition containing the above-mentioned solvent or by using the liquid crystal composition formulated into a form of a liquid-state material such as a molten liquid by heating or the like.

Examples of a method for applying the liquid crystal composition include known methods such as a roll coating method, a gravure printing method, a spin coating method, a wire bar coating method, an extrusion coating method, a direct gravure coating method, a reverse gravure coating method, a die-coating method, a spray method, and an ink jet method.

In the present aspect, examples in which a liquid crystal composition is applied onto a substrate are shown, but the present invention is not limited thereto, and for example, the liquid crystal composition may be applied onto an alignment film provided on a substrate. Details of the substrate and the alignment film will be described later.

[Aligning Step]

The aligning step is a step of aligning the dichroic substance included in the coating film. With this step, a light absorption anisotropic film can be obtained.

The aligning step may have a drying treatment. By the drying treatment, components such as a solvent can be removed from the coating film. The drying treatment may be performed by a method of leaving the coating film at room temperature for a predetermined time (for example, natural drying), or may be performed by a method of heating and/or blowing.

Here, the dichroic substance included in the liquid crystal composition may be aligned by the above-mentioned coating film forming step or drying treatment in some cases. For example, in an aspect in which the liquid crystal composition is prepared as a coating liquid including a solvent, a coating film having light absorption anisotropy (that is, a light absorption anisotropic film) can be obtained by drying the coating film and removing the solvent from the coating film.

The aligning step preferably has a heating treatment. With this heating treatment, the dichroic substance included in the coating film can be aligned, and therefore, the coating film after the heating treatment can be suitably used as the light absorption anisotropic film.

The heating treatment is preferably performed at 10° C. to 250° C., and more preferably performed at 25° C. to 190° C., from the viewpoint of manufacturing suitability and the like. In addition, the heating time is preferably 1 to 300 seconds, and more preferably 1 to 60 seconds.

The aligning step may have a cooling treatment which is carried out after the heating treatment. The cooling treatment is a treatment for cooling the heated coating film to approximately room temperature (20° C. to 25° C.). By the cooling treatment, the alignment of the dichroic substance included in the coating film can be immobilized. The cooling unit is not particularly limited, and can be carried out by a known method.

Through the steps above, a light absorption anisotropic film can be obtained.

In addition, in the present aspect, examples of the method for aligning the dichroic substance included in the coating film include, but are not limited to, the drying treatment, the heating treatment, and the like, and the method can be carried out by a known alignment treatment.

[Other Steps]

A method for producing the light absorption anisotropic film may have a step of curing the light absorption anisotropic film after the aligning step (hereinafter also referred to as a “curing step”).

The curing step is carried out, for example, by heating and/or light irradiation (exposure). Among these, the curing step is preferably carried out by light irradiation.

Various light sources such as infrared light, visible light, and ultraviolet rays can be used as a light source for curing, but the ultraviolet rays are preferable. In addition, the ultraviolet rays may be irradiated while heating at the time of curing or the ultraviolet rays may be irradiated through a filter which transmits only a specific wavelength.

In addition, the exposure may be performed in a nitrogen atmosphere. In a case where curing of the light absorption anisotropic film proceeds by radical polymerization, it is preferable that exposure is performed in a nitrogen atmosphere since inhibition of polymerization by oxygen is reduced.

The light absorption anisotropic film may have an absorption axis in a plane (hereinafter also referred to as “horizontal alignment”) or out of the plane.

In a case where the absorption axis is out of the plane, the absorption axis may substantially coincide with the normal of the light absorption anisotropic film plane (hereinafter also referred to as “vertical alignment”), and may be oblique by 5° to 85° from the normal (hereinafter also referred to as “oblique alignment”).

The absorption axis in a case where the light absorption anisotropic film is horizontally aligned is preferably at more than 85° from the normal of the film plane, and the absorption axis in a case where the light absorption anisotropic film is vertically aligned is preferably at less than 5° from the normal of the film plane. The side-chain type high-molecular-weight liquid crystalline compound contained in the liquid crystal composition of the embodiment of the present invention is suitably used for the light absorption anisotropic film in these three aligned states.

In addition, the alignment degree of the light absorption anisotropic film is preferably 0.7 or more, more preferably 0.85 or more, and particularly preferably 0.93 or more.

Here, the alignment degree can be calculated from the following equation after measuring a light absorption degree with polarized light that vibrates in a direction parallel to the major axis of the dichroic substance in the same plane as the alignment direction of the dichroic substance (the light absorption degree being hereinafter also referred to as “Ap”), and a light absorption degree with polarized light that vibrates in a perpendicular direction in the same plane as the alignment direction of the dichroic substance.

Alignment degree=(Ap−Ac)/(2Ap+Ac)

The measurement of the alignment degree will be described by taking horizontal alignment as an example.

First, a polarizing plate is set on a light source side of a device capable of measuring absorption in the visible region.

Next, a sample is set on a detection side of a polarizing plate so that the light source light is incident from the normal direction of the light absorption anisotropic film plane in the sample, and an absorption spectrum at a position where the absorbance is maximized while rotating the sample is measured (Ap).

Similarly, the absorption spectrum at a position where the absorbance is minimized is measured (Ac).

The alignment degree is calculated from the equation using the values of Ap and Ac at a desired wavelength.

A film thickness of the light absorption anisotropic film is preferably 0.1 to 5.0 μm, and more preferably 0.3 to 1.5 μm. Although depending on a concentration of the dichroic substance in the liquid crystal composition, in a case where the film thickness is 0.1 μm or more, a light absorption anisotropic film having excellent absorbance is obtained, and in a case where the film thickness is 5.0 μm or less, a light absorption anisotropic film having excellent transmittance can be obtained.

[Laminate]

The laminate of an embodiment of the present invention has a substrate and the light absorption anisotropic film of the embodiment of the present invention provided on the substrate.

In addition, the laminate of the embodiment of the present invention may have a λ/4 plate on the light absorption anisotropic film.

Further, the laminate of the embodiment of the present invention may have an alignment film between the substrate and the light absorption anisotropic film.

Moreover, the laminate of the embodiment of the present invention may have a barrier layer between the light absorption anisotropic film and the λ/4 plate.

Hereinafter, the respective layers constituting the laminate of the embodiment of the present invention will be described.

[Substrate]

The substrate can be selected according to the applications of the light absorption anisotropic film, and examples thereof include a glass and a polymer film. A light transmittance of the substrate is preferably 80% or more.

In a case where a polymer film is used as the substrate, it is preferable to use an optically isotropic polymer film. For specific examples and preferred aspects of the polymer, the description in paragraph [0013] of JP2002-22942A can be applied. In addition, even a polymer known in the related art, such as a polycarbonate and a polysulfone that easily expresses birefringence, can also be used, in which the expression has been reduced by molecule modification described in WO2000/26705A.

[Light Absorption Anisotropic Film]

Since the light absorption anisotropic film is as described above, a description thereof will be omitted.

[λ/4 Plate]

The “λ/4 plate” is a plate having a λ/4 function, specifically, a plate having a function of converting a linearly polarized light at a certain specific wavelength into a circularly polarized light (or converting a circularly polarized light to a linearly polarized light).

For example, specific examples of an aspect in which the λ/4 plate has a monolayer structure include a stretched polymer film and a phase difference film having an optically anisotropic layer having a λ/4 function provided on a support, and specific examples of an aspect in which the λ/4 plate has a multilayer structure include a broadband λ/4 plate obtained by laminating λ/4 plate and a λ/2 plate.

The λ/4 plate and the light absorption anisotropic film may be provided in contact with each other, or another layer may be provided between the λ/4 plate and the light absorption anisotropic film. Examples of such a layer include a pressure sensitive adhesive layer or adhesive layer for securing adhesiveness, and a barrier layer.

[Barrier Layer]

In a case where the laminate of the embodiment of the present invention has a barrier layer, the barrier layer is provided between the light absorption anisotropic film and the λ/4 plate. Incidentally, in a case where there is a layer (for example, a pressure sensitive adhesive layer and an adhesive layer) other than the barrier layer between the light absorption anisotropic film and the λ/4 plate, the barrier layer can be provided, for example, between the light absorption anisotropic film and such another layer.

The barrier layer is also called a gas shielding layer (oxygen shielding layer), and has a function of protecting the light absorption anisotropic film from a gas such as oxygen in the air, moisture, compounds included in an adjacent layer, and the like.

With regard to the barrier layer, reference can be made to, for example, the descriptions in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, or paragraphs [0021] to [0031] of JP2005-169994A.

[Alignment Film]

The laminate of the embodiment of the present invention may have an alignment film between the substrate and the light absorption anisotropic film.

The alignment film may be any layer as long as it enables the dichroic substance included in the liquid crystal composition of the embodiment of the present invention to be in a desired alignment state on the alignment film.

Units such as a rubbing treatment of an organic compound (preferably a polymer) on a film surface, oblique vapor deposition of an inorganic compound, formation of a layer having microgrooves, or accumulation of an organic compound (for example, w-tricosanoic acid, dioctadecyl methylammonium chloride, and methyl stearate) by a Langmuir-Blodgett method (LB film) can be provided. Further, an alignment film in which an alignment function is generated by application of an electric field, application of a magnetic field, or light irradiation is also known. Among those, in the present invention, from the viewpoint of easy control of a pretilt angle of the alignment film, an alignment film formed by rubbing is preferable, and from the viewpoint of uniformity of alignment, a photo-alignment film formed by light irradiation is also preferable.

<Rubbing-Treated Alignment Film>

A polymer material used for an alignment film formed by the rubbing treatment is described in many documents, and many commercially available products thereof can be used. In the present invention, a polyvinyl alcohol or a polyimide, and derivatives thereof are preferably used. With regard to the alignment film, reference can be made to the descriptions on page 43, line 24 to page 49, line 8 of WO2001/88574A1. A thickness of the alignment film is preferably 0.01 to 10 μm, and more preferably 0.01 to 1 μm.

<Photo-Alignment Film>

A photo-alignment material used for an alignment film formed by light irradiation is described in a number of documents and the like. In the present invention, preferred examples of the photo-alignment material include the azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, or JP4151746B, the aromatic ester compounds described in JP2002-229039A, the maleimide and/or alkenyl-substituted nadimide compounds having a photo-alignment unit described in JP2002-265541A or JP2002-317013A, the photo-crosslinkable silane derivatives described in JP4205195B or JP4205198B, and the photo-crosslinkable polyimides, polyamides, or esters described in JP2003-520878A, JP2004-529220A, or JP4162850B. The photo-alignment material is more preferably an azo compound, a photocrosslinkable polyimide, a polyamide, or an ester.

The photo-alignment film formed from the material is irradiated with linearly polarized light or non-polarized light to produce a photo-alignment film.

In the present specification, “irradiation of linearly polarized light” and “irradiation of non-polarized light” are each an operation for causing a photoreaction to occur in a photo-alignment material. The wavelength of the light used varies depending on the photo-alignment material used and is not particularly limited as long as it is necessary for the photoreaction. A peak wavelength of light used for light irradiation is preferably 200 nm to 700 nm, and ultraviolet rays having a peak wavelength of light of 400 nm or less are more preferable.

A light source used for light irradiation may be a commonly used light source, for example, a lamp such as a tungsten lamp, a halogen lamp, a xenon lamp, a xenon flash lamp, a mercury lamp, a mercury xenon lamp, and a carbon arc lamp, various lasers [for example, a semiconductor laser, a helium neon laser, an argon ion laser, a helium cadmium laser, and an yttrium aluminum garnet (YAG) laser], a light emitting diode, and a cathode ray tube.

As a unit with which the linearly polarized light is obtained, a method using a polarizing plate (for example, an iodine polarizing plate, a dichroic coloring agent polarizing plate, and a wire grid polarizing plate), a method using a reflective polarizer with a prism-based element (for example, a Glan-Thompson prism) or a Brewster angle, or a method using light emitted from a laser light source having polarized light can be adopted. In addition, only light at a required wavelength may also be selectively irradiated using a filter, a wavelength conversion element, or the like.

With regard to light to be irradiated, in a case of linearly polarized light, a method of irradiating light from the upper surface or the back surface of the alignment film to the surface of the alignment film orthogonally or obliquely is adopted. The incidence angle of light varies depending on the photo-alignment material, but is preferably 0° to 90° (orthogonal), and more preferably 40° to 90°.

In a case of non-polarized light, the alignment film is irradiated with non-polarized light obliquely. The incidence angle is preferably 10° to 80°, more preferably 20° to 60°, and still more preferably 30° to 50°.

The irradiation time is preferably 1 minute to 60 minutes, and more preferably 1 minute to 10 minutes.

In a case where patterning is necessary, a method of performing light irradiation using a photomask as many times as necessary for pattern formation or a method of writing a pattern by laser light scanning can be adopted.

[Use]

The laminate of the embodiment of the present invention can be used as a polarizing element (polarizing plate), and can be, for example, used as a linearly polarizing plate or a circularly polarizing plate.

In a case where the laminate of the embodiment of the present invention does not have an optically anisotropic layer such as a λ/4 plate, the laminate can be used as the linearly polarizing plate.

On the other hand, in a case where the laminate of the embodiment of the present invention has the λ/4 plate, the laminate can be used as the circularly polarizing plate.

[Image Display Device]

The image display device of an embodiment of the present invention has the above-mentioned light absorption anisotropic film or the above-mentioned laminate.

A display element used in the image display device of the embodiment of the present invention is not particularly limited, and examples thereof include a liquid crystal cell, an organic electroluminescence (hereinafter simply referred to as “EL”) display panel, and a plasma display panel.

Among those, a liquid crystal cell or an organic EL display panel is preferable and a liquid crystal cell is more preferable. That is, as the image display device of the embodiment of the present invention, a liquid crystal display device using a liquid crystal cell as a display element or an organic EL display device using an organic EL display panel as a display element is preferable, and the liquid crystal display device is more preferable.

[Liquid Crystal Display Device]

As the liquid crystal display device which is an example of the image display device of the embodiment of the present invention, an aspect thereof having the above-mentioned light absorption anisotropic film and a liquid crystal cell is preferably cited. The liquid crystal display device is more suitably a liquid crystal display device having the above-mentioned laminate (provided that the laminate does not include a λ/4 plate) and a liquid crystal cell.

Furthermore, in the present invention, among the light absorption anisotropic films (laminates) provided on both sides of the liquid crystal cell, the light absorption anisotropic film (laminate) of the embodiment of the present invention is preferably used as the front-side polarizing element, and the light absorption anisotropic film (laminate) of the embodiment of the present invention is more preferably used as the front-side and rear-side polarizing elements.

Hereinafter, the liquid crystal cell constituting the liquid crystal display device will be described in detail.

<Liquid Crystal Cell>

The liquid crystal cell used for the liquid crystal display device is preferably in a vertical alignment (VA) mode, an optically compensated bend (OCB) mode, an in-plane-switching (IPS) mode, or a twisted nematic (TN) mode, but is not limited thereto.

In a TN-mode liquid crystal cell, rod-like liquid crystalline molecules are substantially horizontally aligned and are twist-aligned at 60° to 120° during no voltage application thereto. The liquid crystal cell in the TN mode is most frequently used as a color thin film transistor (ITFT) liquid crystal display device, and is described in many documents.

In a VA-mode liquid crystal cell, rod-like liquid crystalline molecules are substantially vertically aligned during no voltage application thereto. The liquid crystal cell in the VA mode includes (1) a narrowly-defined liquid crystal cell in the VA mode in which rod-like liquid crystalline molecules are substantially vertically aligned with no application of a voltage, and are substantially horizontally aligned with the application of a voltage (described in JP1990-176625A (JP-H02-176625A)), (2) a liquid crystal cell (in the MVA mode) in which the VA mode is made into multi-domains in order to expand the angle of view (described in SID97, Digest of tech. Papers (proceedings) 28 (1997) 845), (3) an liquid crystal cell in a mode (the n-ASM mode) in which rod-like liquid crystalline molecules are substantially vertically aligned with no application of a voltage, and are twistedly aligned in multi-domains with the application of a voltage (described in the proceedings 58 and 59 of Japanese Liquid Crystal Conference (1998)), and (4) a liquid crystal cell in the SURVIVAL mode (announced at LCD International 98). In addition, the liquid crystal cell in the VA mode may be any one of a patterned vertical alignment (PVA) type, an optical alignment type, and a polymer-sustained alignment (PSA) type. With respect to the details of these modes, detailed descriptions can be found in JP2006-215326A and JP2008-538819A.

In an IPS-mode liquid crystal cell, rod-shaped liquid crystalline molecules are aligned substantially parallel with respect to a substrate, and application of an electric field parallel to the substrate surface causes the liquid crystal molecules to respond planarly. The IPS mode displays black in a state where no electric field is applied and a pair of upper and lower polarizing plates have absorption axes which are orthogonal to each other. A method for improving the angle of view by reducing light leakage during black display in an oblique direction using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

[Organic EL Display Device]

Suitable examples of an organic EL display device which is an example of the image display device of the embodiment of the present invention include an aspect in which the organic EL display device has a light absorption anisotropic film, a λ/4 plate, and an organic EL display panel in this order from the visual recognition side.

An aspect in which the organic EL display device has the above-described laminate having a λ/4 plate and an organic EL display panel in this order from the visual recognition side is more suitable. In this case, in the laminate, a substrate, an alignment film provided as necessary, a light absorption anisotropic film, a barrier layer provided as necessary, and a λ/4 plate are arranged in this order from the visual recognition side.

In addition, the organic EL display panel is a display panel configured using an organic EL element in which an organic light emitting layer (organic electroluminescent layer) is sandwiched between electrodes (between a cathode and an anode). The configuration of the organic EL display panel is not particularly limited, and known configurations are employed.

### EXAMPLES

Hereinafter, the present invention will be described in more detail with reference to Examples. The materials, the amounts of materials used, the ratios, the treatment details, the treatment procedure, or the like shown in the following Examples can be appropriately modified without departing from the spirit of the present invention. Therefore, the scope of the present invention will not be restrictively interpreted by the following Examples.

[Synthesis of Side-Chain Type High-Molecular-Weight Liquid Crystalline Compound]

[Synthesis of High-Molecular-Weight Liquid Crystalline Compound (FP1)]

According to the following scheme, a compound (M-1) represented by Formula (M-1) and a compound (F-1) represented by Formula (F-1) were used to synthesize a high-molecular-weight liquid crystalline compound (FP1) represented by Formula (FP1).

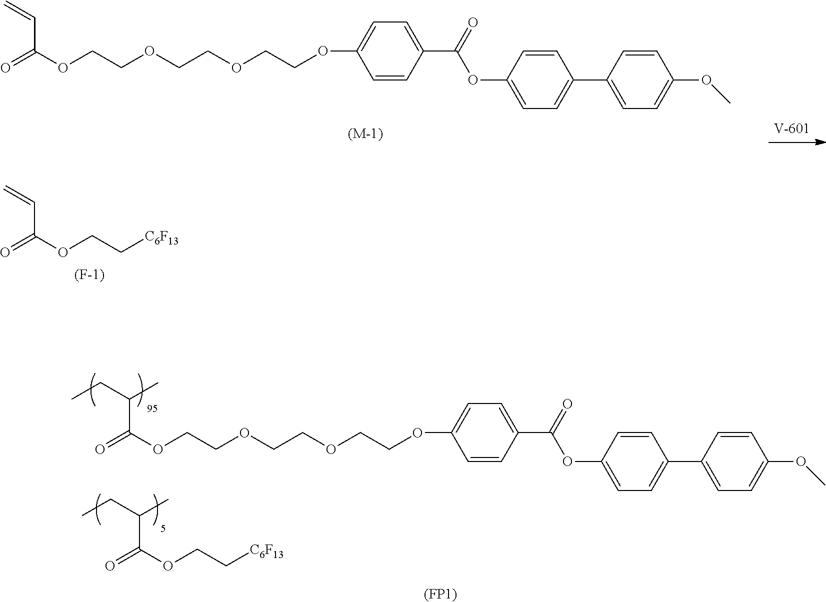

Specifically, first, a dimethylacetamide (DMAc) solution (3 mL) containing 0.98 g of the compound (M-1) and 0.02 g of the compound (F-1) was heated to 80° C. under a nitrogen stream.

13 mg of dimethyl 2,2′-azobis(2-methylpropionate) (product name “V-601”, manufactured by Fujifilm Wako Pure Chemical Industries, Ltd.) was added thereto, and the mixture was heated at 80° C. for 2 hours.

Next, the disappearance of a polymerizable group was confirmed by ¹H-NMR spectrum measurement, the mixture was cooled to room temperature, 300 mL of methanol was then added thereto, followed by filtering, and the residue was washed with methanol to obtain 0.9 g of a high-molecular-weight liquid crystalline compound (FP1) as a white solid.

The weight-average molecular weight (Mw) of the obtained high-molecular-weight liquid crystalline compound (FP1) was 17,100.

[Synthesis of High-Molecular-Weight Liquid Crystalline Compounds (FP2) and (FP3)]

High-molecular-weight liquid crystalline compounds (FP2) and (FP3) represented by Formulae (FP2) and (FP3) were synthesized by the same method as that for the high-molecular-weight liquid crystalline compound (FP1), except that the blending amounts of the compound (M-1) and the compound (F-1) were changed.

The weight-average molecular weight (Mw) of the obtained high-molecular-weight liquid crystalline compound (FP2) was 16,500, and the weight-average molecular weight (Mw) of the high-molecular-weight liquid crystalline compound (FP3) was 15,500.

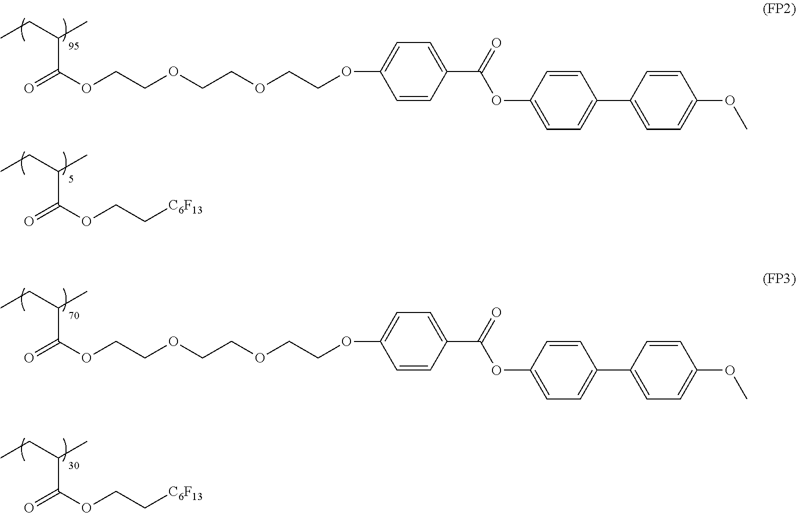

[Synthesis of High-Molecular-Weight Liquid Crystalline Compound (FP4)]

According to the following scheme, a compound (M-1) represented by Formula (M-1), a compound (M-2) represented by Formula (M-2), a compound (M-3) represented by Formula (M-3), and a compound (F-1) represented by Formula (F-1) were used to synthesize a high-molecular-weight liquid crystalline compound (FP4A) represented by Formula (FP4A).

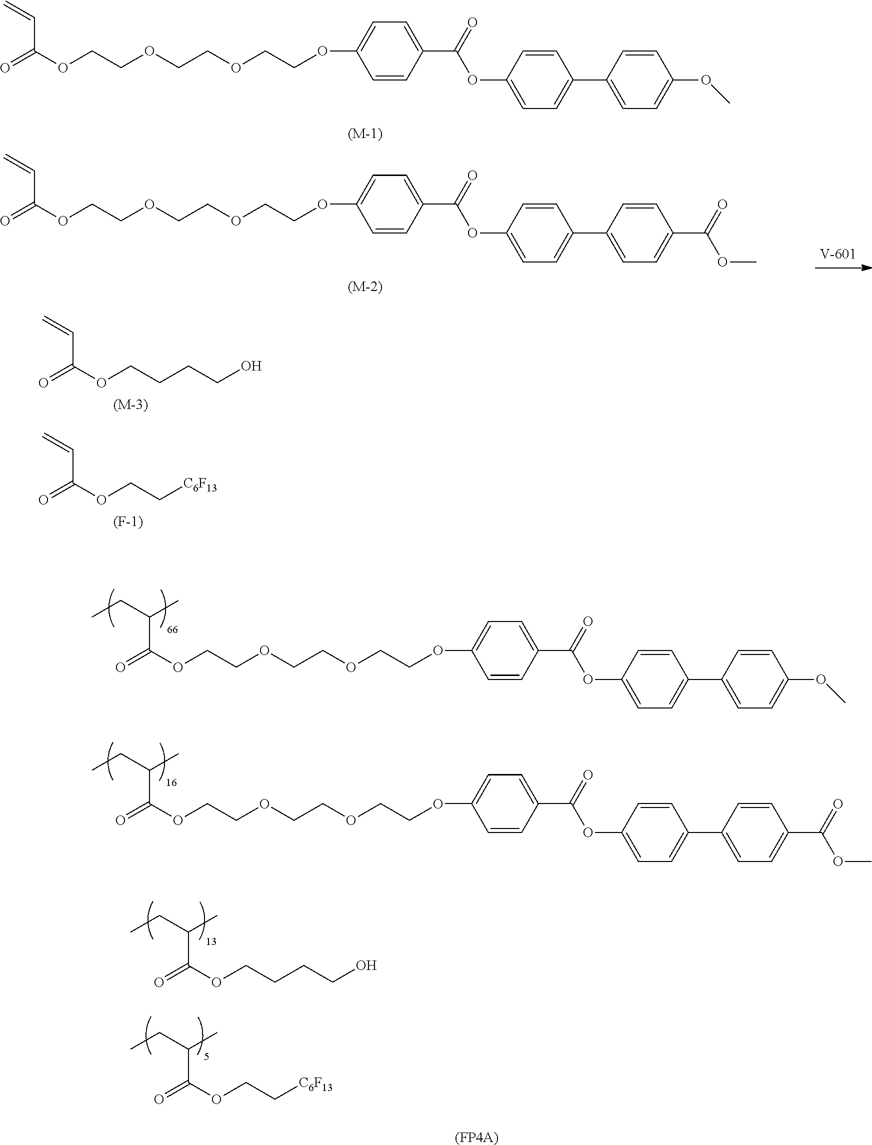

Specifically, an anisole solution (35 ml) containing 10.04 g of the compound (M-1), 2.51 g of the compound (M-2), 1.99 g of the compound (M-3), 0.77 g of the compound (F-4), and 0.242 g of dimethyl 2,2′-azobis(2-methylpropionate) (product name “V-601”, manufactured by Fujifilm Wako Pure Chemical Industries, Ltd.) was added dropwise over 4 hours to anisole (8.3 ml) which had been heated to 80° C. under a nitrogen stream.

After completion of the dropwise addition, the mixture was heated at 80° C. for 4 hours.

Then, after confirming the disappearance of the polymerizable group by ¹H-NMR spectrum measurement, 15.6 ml of 1,3-dimethyl-2-imidazolidinone as an aprotic polar solvent was added thereto, and the mixture was cooled to room temperature. The reaction liquid was added to 245 mL of hexane, followed by filtering, and the residue was washed with hexane and acetone to obtain 14.5 g of a high-molecular-weight liquid crystalline compound (FP4A) as a white solid.

A weight-average molecular weight (Mw) of the obtained high-molecular-weight liquid crystalline compound (FP4A) was 21,300.

Then, according to the following scheme, a high-molecular-weight liquid crystalline compound (FP4) represented by Formula (FP4) was synthesized.

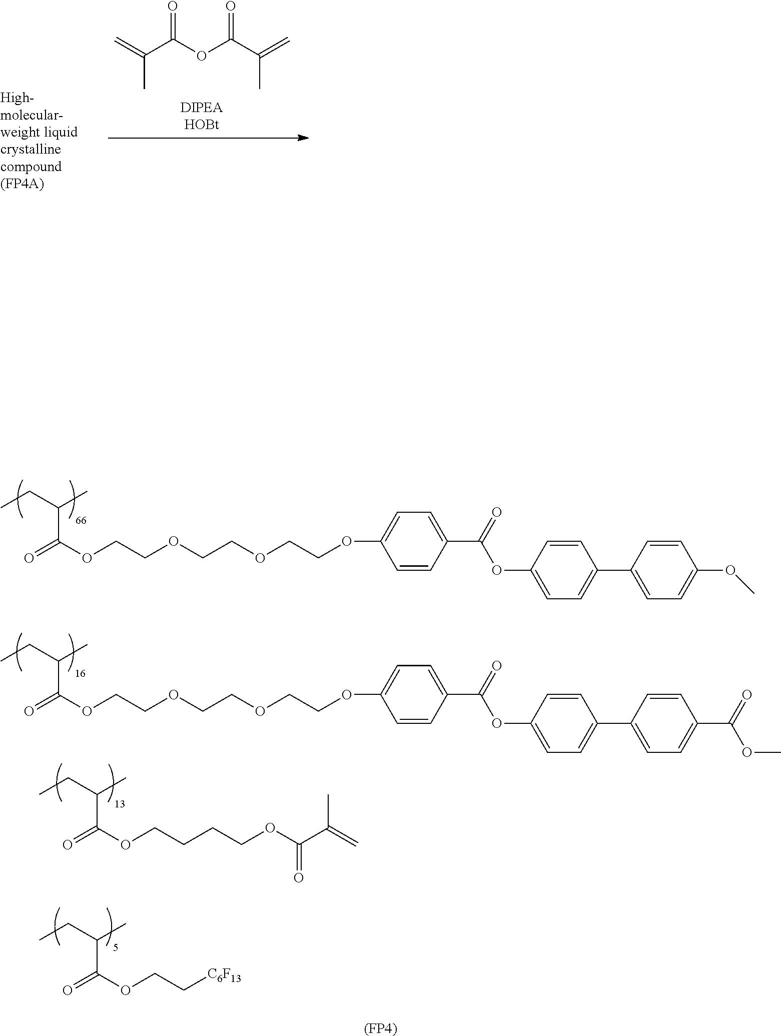

Specifically, 20 ml of a 1,3-dimethyl-2-imidazolidinone solution containing 10.0 g of the high-molecular-weight liquid crystalline compound (FP4A), 3.2 g of 1-hydroxybenzotriazole (HOBt), and 20.82 ml of N,N-diisopropylethylamine (DIPEA) was heated to 40° C., and 17.78 ml of anhydrous methacrylic anhydride was added dropwise thereto.

After completion of the dropwise addition, the reaction liquid was stirred at 40° C. for 6 hours, and then 10 ml of acetone was added thereto.

Then, the reaction liquid was added to a mixed solvent (185 ml) of hexane and acetone, followed by filtering, and the residue was washed with hexane and acetone to obtain 8.6 g of a high-molecular-weight liquid crystalline compound (FP4) as a white solid.

A weight-average molecular weight (Mw) of the obtained high-molecular-weight liquid crystalline compound (FP4) was 21,700.

[Synthesis of High-Molecular-Weight Liquid Crystalline Compound (FP5)]

A high-molecular-weight liquid crystalline compound (FP5) represented by Formula (FP5) was synthesized by the same method as that for the high-molecular-weight liquid crystalline compound (FP4), except that the blending amounts of the compound (M-1), the compound (M-2), the compound (M-3), and the compound (F-1) were changed.

A weight-average molecular weight (Mw) of the obtained high-molecular-weight liquid crystalline compound (FP5) was 13,000.

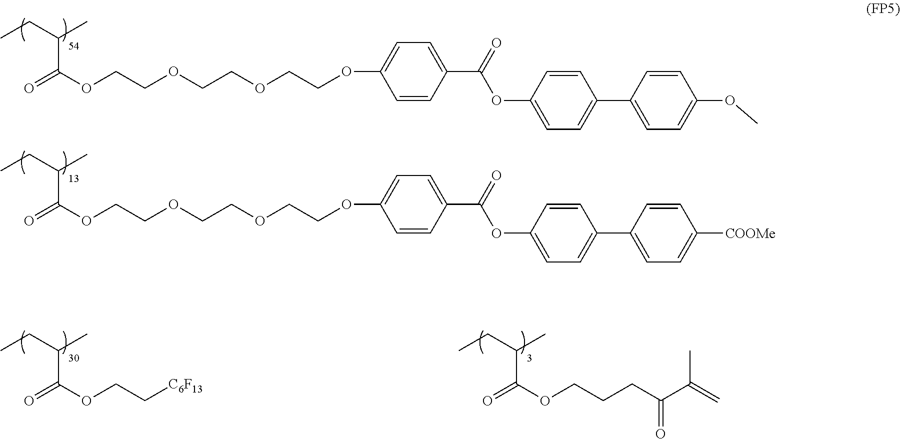

[Synthesis of High-Molecular-Weight Liquid Crystalline Compound (FP6)]

According to the following scheme, a compound (M-1) represented by Formula (M-1), a compound (M-2) represented by Formula (M-2), and a compound (F-2) represented by Formula (F-2) were used to synthesize a high-molecular-weight liquid crystalline compound (FP6) represented by Formula (FP6).

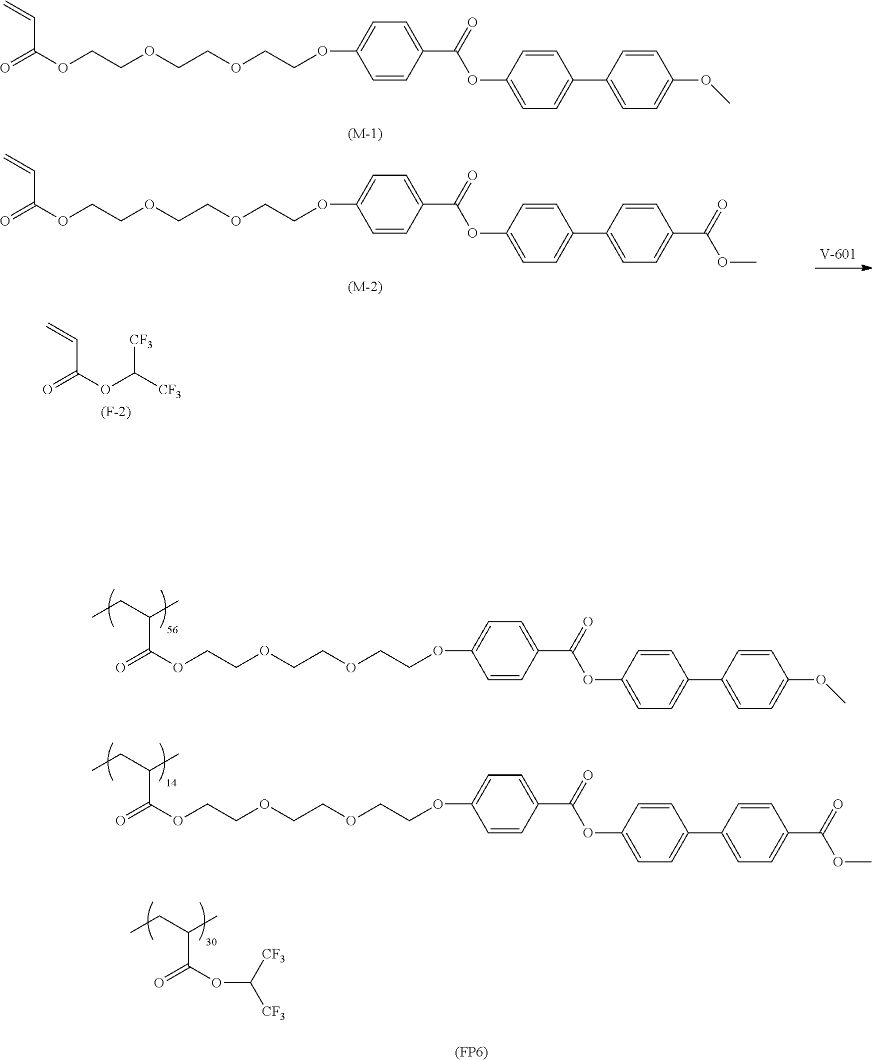

Specifically, an anisole solution (35 ml) containing 8.57 g of the compound (M-1), 2.14 g of the compound (M-2), 4.59 g of the compound (F-2), and 0.335 g of dimethyl 2,2′-azobis(2-methylpropionate) (product name “V-601”, manufactured by Fujifilm Wako Pure Chemical Industries, Ltd.) was added dropwise over 4 hours to anisole (8.3 ml) which had been heated to 80° C. under a nitrogen stream.

After completion of the dropwise addition, the mixture was heated at 80° C. for 4 hours.

Then, after confirming the disappearance of the polymerizable group by ¹H-NMR spectrum measurement, 15.3 ml of 1,3-dimethyl-2-imidazolidinone as an aprotic polar solvent was added thereto, and the mixture was cooled to room temperature. The reaction liquid was added to 245 mL of hexane, followed by filtering, and the residue was washed with hexane and acetone to obtain 13.14 g of a high-molecular-weight liquid crystalline compound (FP6) as a white solid.

A weight-average molecular weight (Mw) of the obtained high-molecular-weight liquid crystalline compound (FP6) was 14,000.

[Synthesis of High-Molecular-Weight Liquid Crystalline Compound (FP7)]

According to the following scheme, a compound (M-1) represented by Formula (M-1), a compound (M-2) represented by Formula (M-2), and a compound (F-1) represented by Formula (F-1) were used to synthesize a high-molecular-weight liquid crystalline compound (FP7) represented by Formula (FP7).

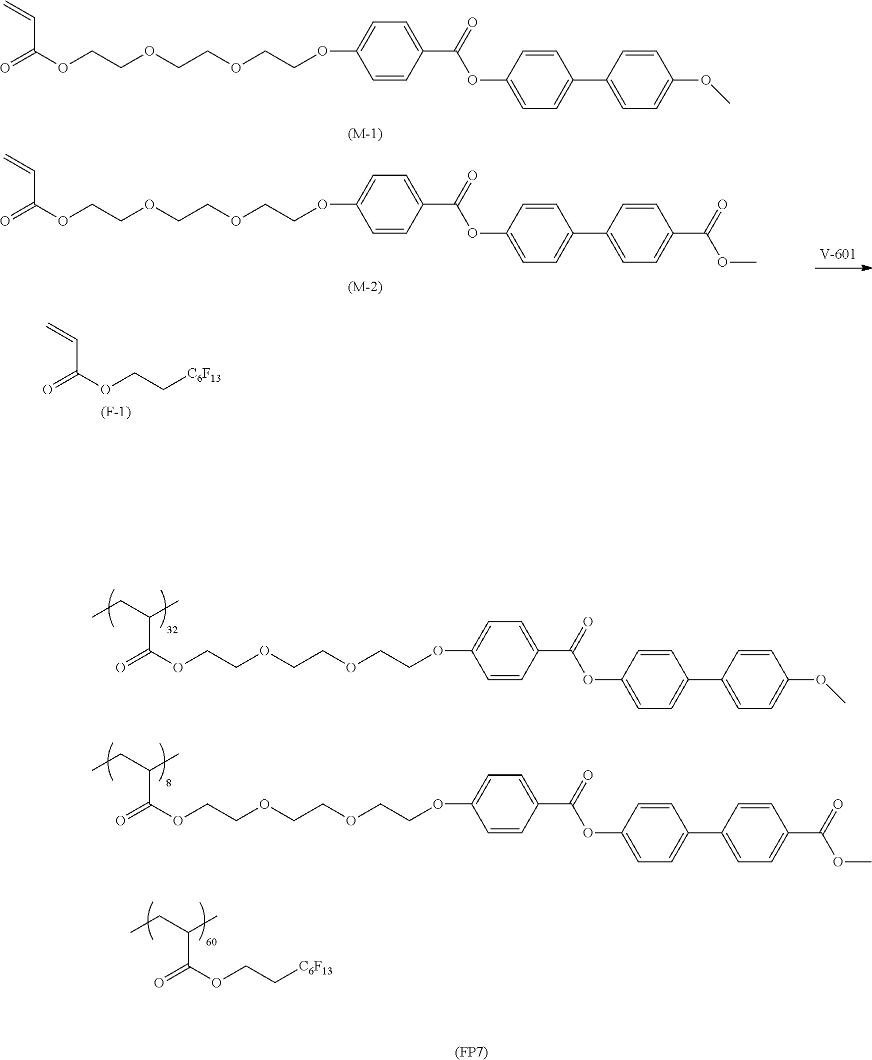

Specifically, an anisole solution (35 ml) containing 4.90 g of the compound (M-1), 1.22 g of the compound (M-2), 9.18 g of the compound (F-1), and 0.242 g of dimethyl 2,2′-azobis(2-methylpropionate) (product name “V-601”, manufactured by Fujifilm Wako Pure Chemical Industries, Ltd.) was added dropwise over 4 hours to anisole (8.3 ml) which had been heated to 80° C. under a nitrogen stream.

After completion of the dropwise addition, the mixture was heated at 80° C. for 4 hours.

Then, after confirming the disappearance of the polymerizable group by ¹H-NMR spectrum measurement, 15.3 ml of 1,3-dimethyl-2-imidazolidinone as an aprotic polar solvent was added thereto, and the mixture was cooled to room temperature. The reaction liquid was added to 245 mL of hexane, followed by filtering, and the residue was washed with hexane and acetone to obtain 13.00 g of a high-molecular-weight liquid crystalline compound (FP7) as a white solid.

A weight-average molecular weight (Mw) of the obtained high-molecular-weight liquid crystalline compound (FP7) was 18,000.

### Example 1

[Manufacture of Alignment Film]

A glass substrate (manufactured by Central Glass Co., Ltd., blue plate glass, size of 300 mm×300 mm, thickness of 1.1 mm) was washed with an alkali detergent, pure water was then poured thereinto, and then the glass substrate was dried.

The following composition 1 for forming an alignment film was applied onto a dried glass substrate using a bar of #12, and the applied composition 1 for forming an alignment film was dried at 110° C. for 2 minutes to form a coating film on the glass substrate.

The obtained coating film was subjected to a rubbing treatment (rotation speed of a roller: 1,000 rotations/spacer thickness of 2.9 mm, and stage speed of 1.8 m/min) once to manufacture an alignment film 1 on the glass substrate.

Composition of Composition 1 for Forming Alignment Film

| | |
|---|---|
| Modified polyvinyl alcohol | 2.00 parts by mass |
| (Formula (PVA-1)) | |
| Water | 74.08 parts by mass |
| Methanol | 23.86 parts by mass |
| Photopolymerization initiator | 0.06 parts by mass |
| (IRGACURE 2959, manufactured by BASF) | |

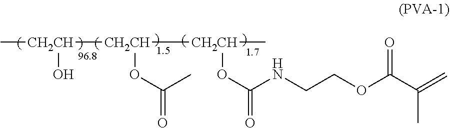

Furthermore, in Formula (PVA-1), the numerical value in the repeating unit represents % by mole of each repeating unit with respect to all the repeating units in the modified vinyl alcohol.

[Manufacture of Polarizer 1A]

A liquid crystalline composition 1 having the following composition was spin-coated on the obtained alignment film 1 at 1,000 rpm to form a coating film. Next, the coating film was heated at 140° C. for 40 seconds, and the coating film 1 was cooled to room temperature (23° C.). Subsequently, the film was heated at 85° C. for 10 seconds and cooled again to room temperature.

Thereafter, the film was irradiated with light for 60 seconds under an irradiation condition of an illuminance of 28 mW/cm² using a high-pressure mercury lamp to form a polarizer (light absorption anisotropic film) 1A on the alignment film A.

Composition of liquid crystal composition 1

| | |
|---|---|
| High-molecular-weight liquid | 3.721 parts by mass |
| crystalline compound (FP1) | |
| The following dichroic substance Y1 | 0.298 parts by mass |
| The following dichroic substance M1 | 0.347 parts by mass |
| The following dichroic substance C1 | 0.546 parts by mass |
| The following interface modifier F1 | 0.050 parts by mass |
| Polymerization initiator I1 | 0.039 parts by mass |
| (IRGACURE 819: manufactured by BASF) | |
| Chloroform | 95.00 parts by mass |

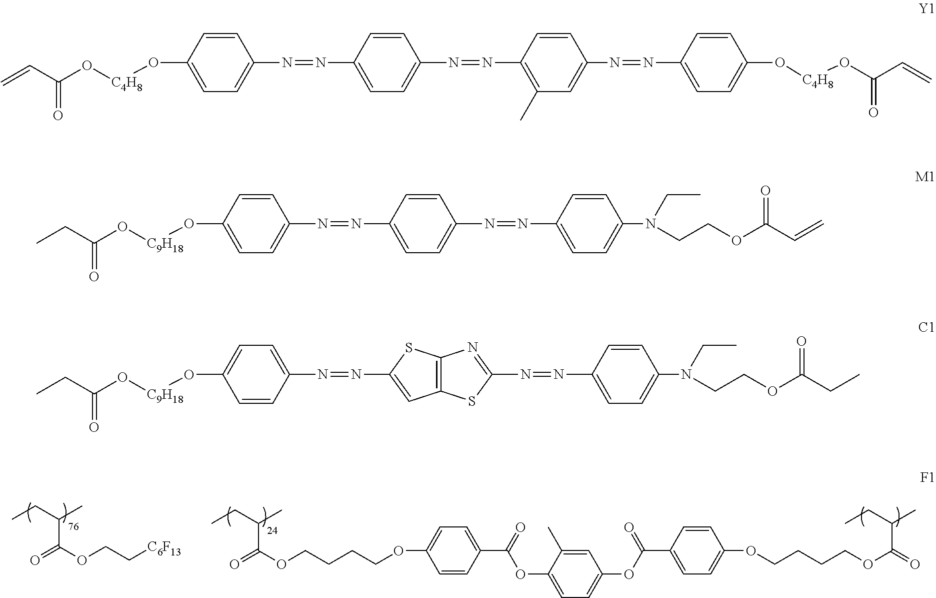

[Manufacture of Circularly Polarizing Plate]

A pressure sensitive adhesive (SK-2057, manufactured by Soken Chemical & Engineering Co., Ltd.) was applied to a glass side of the polarizer 1A manufactured above to form a pressure sensitive adhesive layer, and Pure Ace WR (manufactured by Teijin Limited) as a λ/4 plate was bonded thereto to manufacture a circularly polarizing plate.

### Examples 2 to 8 and Comparative Example 1

A circularly polarizing plate was manufactured by the same method as in Example 1, except that the composition of the liquid crystal composition 1 was changed to a composition shown in Table 1 below.

[Evaluation]

A surface on the λ/4 plate side of the manufactured circularly polarizing plate was roughened with sandpaper and then treated with a black ink to eliminate backside reflection, and in this state, an adapter ARV-474 was attached to Spectrophotometer V-550 (manufactured by JASCO Corporation), an integrated reflectance at an incidence angle of 5 was measured in a wavelength range of 380 to 780 nm, an average reflectance thereof was calculated, and the antireflection property was evaluated according to the following standard. The results are shown in Table 1 below.

A: The reflectance is 5.9% or less.

B: The reflectance is more than 5.9% and 6.5% or less.

C: The reflectance is more than 6.5%.

TABLE 1

| | Side-chain | | | | | | | | | | | | | | |
|---|---|---|---|---|---|---|---|---|---|---|---|---|---|---|---|
| | type | | | | | | | | | | | | | Content of | |
| | high- | | | | | | | | | | | | | side-chain | |
| | molecular- | | | | | | | | | | | | | type | |
| | weight | | Other liquid | | | | | | | | | | | high- | |
| | liquid | | crystalline | | Dichroic substance | | | | | Poly- | | | | molecular- | |
| | crystalline | | compounds | | Y1 | M1 | C1 | | | merization | | | | weight | |
| | compound | | | Parts | Parts | Parts | Parts | Surfactant | | initiator | | Chloroform | Content of | liquid | Re- |
| | | Parts by | | by | by | by | by | | Parts by | | Parts by | Parts by | repeating | crystalline | flect- |
| | Type | mass | Type | mass | mass | mass | mass | Type | mass | Type | mass | mass | unit F | compound | ance |
| Example 1 | FP1 | 3.721 | — | — | 0.298 | 0.347 | 0.546 | F1 | 0.050 | I1 | 0.039 | 95.0 | 2% by weight | 74.4% by weight | B |
| Example 2 | FP1 | 1.116 | L1 | 2.605 | 0.298 | 0.347 | 0.546 | F1 | 0.050 | I1 | 0.039 | 95.0 | 2% by weight | 22.3% by weight | B |
| Example 3 | FP3 | 0.186 | L2 | 3.535 | 0.298 | 0.347 | 0.546 | F1 | 0.050 | I1 | 0.039 | 95.0 | 30% by weight | 3.7% by weight | B |
| Example 4 | FP2 | 0.744 | L3 | 2.977 | 0.298 | 0.347 | 0.546 | F1 | 0.050 | I1 | 0.039 | 95.0 | 5% by weight | 14.9% by weight | A |
| Example 5 | FP4 | 0.744 | L3/ | 2.382/ | 0.298 | 0.347 | 0.546 | F1 | 0.050 | I1 | 0.039 | 95.0 | 5% by | 14.9% | A |
| | | | LM1 | 0.595 | | | | | | | | | weight | by weight | |
| Example 6 | FP5 | 0.744 | L3 | 2.977 | 0.298 | 0.347 | 0.546 | F1 | 0.050 | I1 | 0.039 | 95.0 | 40% by weight | 14.9% by weight | A |
| Example 7 | FP6 | 0.744 | L3 | 2.977 | 0.298 | 0.347 | 0.546 | F1 | 0.050 | I1 | 0.039 | 95.0 | 30% by weight | 14.9% by weight | A |
| Example 8 | FP7 | 0.020 | L3 | 3.706 | 0.297 | 0.346 | 0.544 | F1 | 0.049 | I1 | 0.039 | 95.0 | 60% by weight | 0.4% by weight | B |
| Comparative | — | — | L3 | 4.465 | 0.357 | 0.417 | 0.655 | F1 | 0.060 | I1 | 0.046 | 95.0 | — | 0.0% | C |
| Example 1 | | | | | | | | | | | | | | by weight | |

The structural formulae of the side-chain type high-molecular-weight liquid crystalline compounds and other liquid crystalline compounds in Table 1 are as follows.

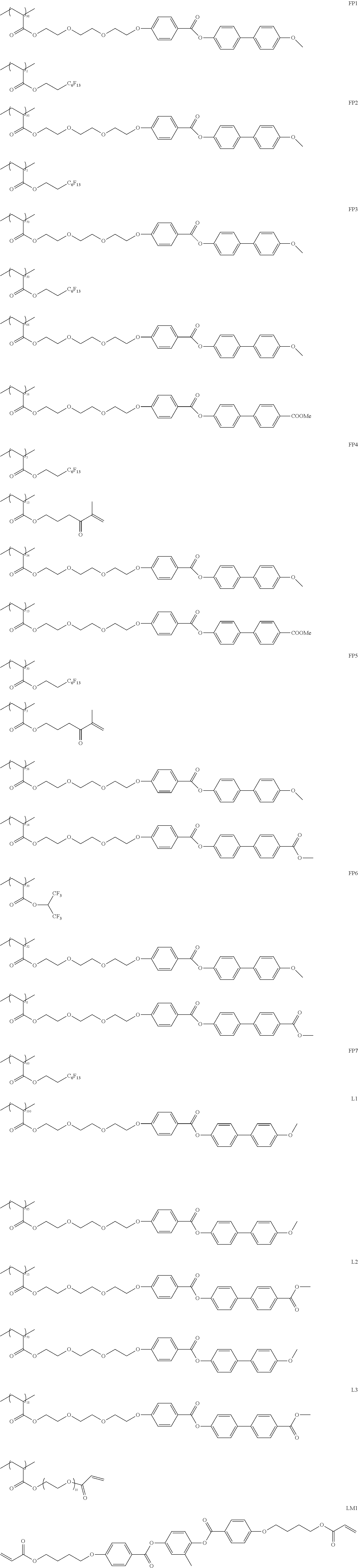

From the results shown in Table 1 above, it was found that in a case where a side-chain type high-molecular-weight liquid crystalline compound having the repeating unit M including a mesogenic group and the repeating unit F including a fluorine atom is not blended, the reflectance of a light absorption anisotropic film thus formed is increased (Comparative Example 1).

In contrast, it was found that in a case where the side-chain type high-molecular-weight liquid crystalline compound having the repeating unit M including a mesogenic group and the repeating unit F including a fluorine atom is blended, the reflectance of a light absorption anisotropic film thus formed is decreased (Examples 1 to 8).

In particular, from the results of Examples 4 and 6 to 8, it was found that in a case where a content of the side-chain type high-molecular-weight liquid crystalline compound is 0.5% by mass or more with respect to a total solid content of the liquid crystal composition, the reflectance of the light absorption anisotropic film is further decreased.

Furthermore, in Examples 2 to 8, a difference (Δ log P) between the log P values of the side-chain type high-molecular-weight liquid crystalline compound having the repeating unit M including a mesogenic group and the repeating unit F including a fluorine atom and the liquid crystalline compound was in the range of −3.2 to 2.2.

### Examples 9 to 15

A polarizer (light absorption anisotropic film) was manufactured by the same method as in Example 1, except that the composition of the liquid crystal composition 1 was changed to a composition shown in Table 2 below.

Next, the polarizer was further heated at 45° C. for 15 minutes and allowed to stand at room temperature for 1 hour to manufacture light absorption anisotropic films 9A to 15A.

In addition, a circularly polarizing plate was manufactured by the same method as in Example 1, except that the polarizer 1A was changed to the light absorption anisotropic films 9A to 15A.

[Evaluation]

[Surface Condition]

One linearly polarizer was inserted into each of the light source side and the objective lens side of an optical microscope (product name “ECLIPSE E600-POL” manufactured by Nikon Corporation), and arranged to be offset by 90°. The light absorption anisotropic films 9A to 15A manufactured above were set on a sample table, and five places were randomly selected from the light absorption anisotropic films 9A to 15A thus set, and observed using a microscope with an objective lens at a magnification of 20 times. An average value of the numbers of defects in the five measured places was calculated, and defect evaluation was performed according to the following evaluation standard. The results are shown in Table 2 below.

A: The average value of numbers of defects is less than 2.

B: The average value of numbers of defects is 2 or more.

[Reflectance]

For the manufactured circularly polarizing plate, an average reflectance was calculated by the same method as in Example 1, and the antireflection property was evaluated. The results are shown in Table 2 below.

TABLE 2

| | Side-chain | | | | | | | | | | | | | | | | |
|---|---|---|---|---|---|---|---|---|---|---|---|---|---|---|---|---|---|
| | type | | | | | | | | | | | | | Content | | | |
| | high- | | | | | | | | | | | | | of side- | | | |
| | molecular- | | | | | | | | | | | | | chain | | | |
| | weight | | Other | | | | | | | | | | | type | | | |
| | liquid | | liquid | | Dichroic | | | | | Poly- | | | | high- | | | |
| | crystalline | | crystalline | | substance | | | | | merization | | Chloro- | | molecular- | | | |
| | compound | | compounds | | Y1 | M1 | C1 | Surfactant | | initiator | | form | Content | weight | | Sur- | |
| | | Parts | | Parts | Parts | Parts | Parts | | Parts | | Parts | Parts | of | liquid | | face | Re- |
| | | by | | by | by | by | by | | by | | by | by | repeating | crystalline | | con- | flect- |
| | Type | mass | Type | mass | mass | mass | mass | Type | mass | Type | mass | mass | unit F | compound | ΔlogP | dition | ance |
| Example 9 | FP1 | 1.116 | L1 | 2.605 | 0.298 | 0.347 | 0.546 | F1 | 0.050 | I1 | 0.039 | 95.0 | 2% by weight | 22.3% by weight | 0.05 | A | A |
| Example 10 | FP3 | 0.186 | L2 | 3.535 | 0.298 | 0.347 | 0.546 | F1 | 0.050 | I1 | 0.039 | 95.0 | 30% by weight | 3.7% by weight | 0.66 | A | A |
| Example 11 | FP2 | 0.744 | L3 | 2.977 | 0.298 | 0.347 | 0.546 | F1 | 0.050 | I1 | 0.039 | 95.0 | 5% by weight | 14.9% by weight | 0.87 | A | A |
| Example 12 | FP7 | 0.744 | L3 | 2.977 | 0.298 | 0.347 | 0.546 | F1 | 0.050 | I1 | 0.039 | 95.0 | 40% by weight | 14.9% by weight | 2.18 | A | A |
| Example 13 | FP6 | 0.744 | LM1 | 2.977 | 0.298 | 0.347 | 0.546 | F1 | 0.050 | I1 | 0.039 | 95.0 | 30% by weight | 14.9% by weight | −3.23 | A | A |
| Example 14 | FP7 | 0.744 | LM2 | 2.977 | 0.298 | 0.347 | 0.546 | F1 | 0.050 | I3 | 0.039 | 96.9 | 62% by weight | 14.9% by weight | 4.08 | B | B |
| Example 15 | FP6 | 0.744 | LM3 | 2.977 | 0.298 | 0.347 | 0.546 | F1 | 0.050 | I4 | 0.039 | 97.9 | 63% by weight | 14.9% by weight | −4.18 | B | B |

From the results shown in Table 2 above, it was found that in a case where a difference (Δ log P) in log P values between the side-chain type high-molecular-weight liquid crystalline compound having the repeating unit M including a mesogenic group and the repeating unit F including a fluorine atom and the liquid crystalline compound is −3.2 to 2.2, the surface condition of a light absorption anisotropic film thus formed is improved and the reflectance is also decreased (Examples 9 to 15).

### Example 16

An optical film B of Example 16 was produced as follows.

[Manufacture of Light Absorption Anisotropic Film 2]

The following liquid crystal composition 2 was continuously applied on the alignment film 1 used in Example 1 with a wire bar, heated at 120° C. for 60 seconds, and then cooled to room temperature (23° C.).

Subsequently, the film was heated at 80° C. for 60 seconds and cooled again to room temperature.

Thereafter, a light absorption anisotropic film 2 was manufactured on the alignment film 1 by taking the metallic sphere out, followed by irradiating with light using a light emitting diode (LED) lamp (center wavelength of 365 nm) for 2 seconds under irradiation conditions of an illuminance of 200 mW/cm². A film thickness of the light absorption anisotropic film 2 was 3.5 μm.

As a result, an optical film B in which the light absorption anisotropic film 2 was laminated on the alignment film 1 of a TAC film 1 with an alignment film was obtained.

Composition of liquid crystal composition 2

| | |
|---|---|
| High-molecular-weight liquid | 8.354 parts by mass |
| crystalline compound (the FP1) | |
| The following dichroic substance Y1 | 0.571 parts by mass |
| The dichroic substance M1 | 0.137 parts by mass |
| The dichroic substance C1 | 1.027 parts by mass |
| The following interface modifier F2 | 0.004 parts by mass |
| The following vertical alignment agent B1 | 0.125 parts by mass |
| The following vertical alignment agent B2 | 0.125 parts by mass |
| The polymerization initiator I1 | 0.157 parts by mass |
| Cyclopentanone (solvent) | 89.500 parts by mass |

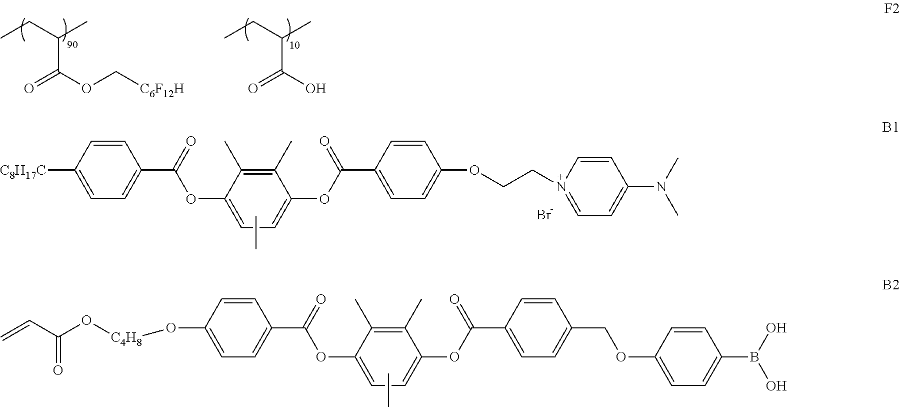

### Examples 17 to 22 and Comparative Example 2

Each optical film of Examples 17 to 22 and Comparative Example 2 was manufactured in the same manner as the optical film B of Example 16, except that the liquid crystal composition was changed to a liquid crystal composition having the composition shown in Table 3 below.

Furthermore, in each of the light absorption anisotropic films included in the optical films of Examples 16 to 22 and Comparative Example 2, the high-molecular-weight liquid crystalline compound and the dichroic substance were vertically aligned.

[Evaluation]

[Alignment Degree]

Using each optical film of Examples and Comparative Examples, a Mueller matrix of the vertical polarizing layer at a wavelength λ was measured every 10 degrees from a polar angle of −50 degrees to 50 degrees with AxoScan OPMF-1 (manufactured by Opto Science, Inc.). After removing the influence of surface reflection, ko [λ] and ke [λ] were calculated by fitting to the following theoretical equation considering Snell's formula and Fresnel's formula.

k=−log P(T)×λ/(4πd)

From the obtained ko [λ] and ke [λ], the absorbance and the dichroic ratio in the in-plane direction and the film thickness direction were calculated, and finally, the vertical alignment degree was determined. In addition, the influence of surface reflection was removed, the measurement results at a polar angle of 0 degrees were used as a front transmittance, and based on the obtained vertical alignment, the alignment degrees were evaluated according to the following evaluation standard.

The results are shown in Table 3 below.

A: The vertical alignment degree was 0.965 or more.

B: The vertical alignment degree is less than 0.965 and 0.935 or more.

C: The vertical alignment degree is less than 0.935.

[Reflectance]

A pressure sensitive adhesive (SK-2057, manufactured by Soken Chemical & Engineering Co., Ltd.) was applied to a side opposite to the surface on which each optical film of Examples and Comparative Examples had been applied, thereby forming a pressure sensitive adhesive layer, and Pure Ace WR (manufactured by Teijin Limited) was bonded thereto. Next, a surface on the Pure Ace WR side was roughened with sandpaper and then treated with a black ink to eliminate backside reflection, and in this state, an adapter ARV-474 was attached to Spectrophotometer V-550 (manufactured by JASCO Corporation), an integrated reflectance at an incidence angle of 5° was measured in a wavelength range of 380 to 780 nm, an average reflectance thereof was calculated, and the antireflection property was evaluated according to the following standard. The results are shown in Table 1 below.

A: The reflectance is 5.9% or less.

B: The reflectance is more than 5.9% and 6.5% or less.

C: The reflectance is more than 6.5%.

TABLE 3

| | Side-chain type | | | | | | | | | | | | |
|---|---|---|---|---|---|---|---|---|---|---|---|---|---|
| | high-molecular- | | | | | | | | | | | Vertical | |
| | weight liquid | | Other liquid | | Dichroic substance | | | | | Poly- | | alignment | |
| | crystalline | | crystalline | | Y1 | M1 | C1 | Surfactant | | merization | | agent A | |
| | compound | | compounds | | Parts | Parts | Parts | | Parts | initiator | | | Parts |
| | | Parts by | | Parts by | by | by | by | | by | | Parts by | | by |
| | Type | mass | Type | mass | mass | mass | mass | Type | mass | Type | mass | Type | mass |
| Example 16 | FP1 | 8.354 | — | — | 0.571 | 0.137 | 1.027 | F2 | 0.004 | I1 | 0.157 | B1 | 0.125 |
| Example 17 | FP2 | 0.031 | L2 | 8.329 | 0.570 | 0.136 | 1.023 | F2 | 0.004 | I1 | 0.156 | B1 | 0.125 |
| Example 18 | FP2 | 2.089 | L2 | 6.266 | 0.571 | 0.137 | 1.027 | F2 | 0.004 | I1 | 0.157 | B1 | 0.125 |
| Example 19 | FP3 | 1.880 | L3 | 6.474 | 0.571 | 0.137 | 1.027 | F2 | 0.004 | I1 | 0.157 | B1 | 0.125 |
| Example 20 | FP5 | 2.004 | L3/ | 2.510/ | 0.577 | 0.138 | 1.037 | F2 | 0.004 | I1 | 0.158 | B1 | 0.127 |
| | | | LM1 | 0.628 | | | | | | | | | |
| Example 21 | FP5 | 7.310 | L3 | 1.044 | 0.571 | 0.137 | 1.027 | F2 | 0.004 | I1 | 0.157 | B1 | 0.125 |
| Example 22 | FP5 | 1.566 | L3 | 6.788 | 0.571 | 0.137 | 1.027 | F2 | 0.004 | I1 | 0.157 | B1 | 0.125 |
| Comparative | — | — | | 4.190/ | 0.566 | 0.135 | 1.016 | F2 | 0.004 | I1 | 0.155 | B1 | 0.124 |
| Example 2 | | | | 4.180 | | | | | | | | | |

| | |
|---|---|
| Vertical | Cyclo- |

| | | | |
|---|---|---|---|
| alignment | | penta- | |
| agent B | THF | none | Content of side-chain type |

| | | Parts | Parts | Parts | Content of | high-molecular-weight | Align- | Re- |
|---|---|---|---|---|---|---|---|---|
| | | by | by | by | repeating | liquid crystalline | ment | flect- |
| | Type | mass | mass | mass | unit F | compound | degree | ance |
| Example 16 | B2 | 0.125 | 0.0 | 89.5 | 2.0 | 79.6% by weight | B | A |
| Example 17 | B2 | 0.125 | 0.0 | 89.5 | 5.0 | 0.3% by weight | B | A |
| Example 18 | B2 | 0.125 | 0.0 | 89.5 | 5.0 | 19.9% by weight | A | A |
| Example 19 | B2 | 0.125 | 0.0 | 89.5 | 30.0 | 17.9% by weight | A | A |
| Example 20 | B2 | 0.127 | 0.0 | 89.5 | 30.0 | 19.1% by weight | A | A |
| Example 21 | B2 | 0.125 | 0.0 | 89.5 | 30.0 | 69.6% by weight | A | A |
| Example 22 | B2 | 0.125 | 0.0 | 89.5 | 30.0 | 14.9% by weight | A | A |
| Comparative | B2 | 0.124 | 0.0 | 89.5 | — | 0.0% by weight | C | C |
| Example 2 | | | | | | | | |

From the results shown in Table 3 above, it was found that in a case where a side-chain type high-molecular-weight liquid crystalline compound having the repeating unit M including a mesogenic group and the repeating unit F including a fluorine atom is blended, the alignment degree can be increased even the high-molecular-weight liquid crystalline compound and the dichroic substance being vertically aligned, and the reflectance is decreased (Examples 16 to 22).

Furthermore, in Examples 17 to 22, a difference (Δ log P) between the log P values of the side-chain type high-molecular-weight liquid crystalline compound having the repeating unit M including a mesogenic group and the repeating unit F including a fluorine atom and the liquid crystalline compound was in the range of −3.2 to 2.2.

### Example 23

The light absorption anisotropic film C of Example 23 was prepared as follows.

<Manufacture of Transparent Support>

A surface of a cellulose acylate film 1 (TAC substrate having a thickness of 40 μm; TG40, manufactured by Fujifilm Corporation) was saponified with an alkali liquid, and the above-mentioned composition 1 for forming an alignment film was applied thereonto with a wire bar. The support on which the coating film had been formed was dried with warm air at 60° C. for 60 seconds and further with warm air at 100° C. for 120 seconds to obtain a TAC film with an alignment layer.

A film thickness thereof was 0.5 μm.

Further, the manufactured TAC film with an alignment layer was used after subjecting the alignment film surface to a rubbing treatment.

<Preparation of Composition Liquid 4 for Forming Photo-Alignment Layer>

A composition liquid 4 for forming a photo-alignment layer was prepared with the following composition, dissolved for 1 hour with stirring, and filtered through a 0.45 μm filter.

Composition liquid 4 for forming photo-alignment layer

| | |
|---|---|
| The following photo-alignment material PA-1 | 0.3 parts by mass |
| 2-Butoxyethanol | 41.6 parts by mass |
| Dipropylene glycol monomethyl ether | 41.6 parts by mass |
| Pure water | 16.5 parts by mass |

Photo-Alignment Material PA-1

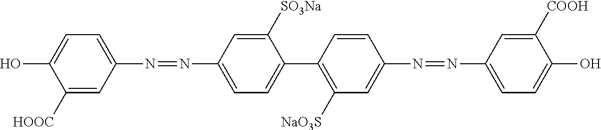

The following composition liquid 4 for forming a photo-alignment layer was applied onto the alignment film and dried at 60° C. for 2 minutes to obtain a TAC film with a photo-alignment film. The obtained coating film was irradiated with ultraviolet rays (irradiation amount of 2,000 mJ/cm²) from a polar angle of 30° using an ultraviolet exposure device to manufacture a transparent support with a photo-alignment layer having a thickness of 0.03 μm.

<Manufacture of Light Absorption Anisotropic Film>

The following composition 5 for forming a light absorption anisotropic film was applied onto the manufactured TAC film with an alignment layer with a wire bar.

Next, the coating layer C was heated at 120° C. for 30 seconds, and the coating layer P1 was cooled until it reached 100° C.

Thereafter, the coating layer was irradiated with light for 2 seconds under an irradiation condition of an illuminance of 200 mW/cm² at room temperature (25° C.), using a LED lamp (center wavelength of 365 nm) to manufacture a light absorption anisotropic film C on the alignment layer 1. Furthermore, the high-molecular-weight liquid crystalline compound and the dichroic substance included in the manufactured light absorption anisotropic film were obliquely aligned with respect to the film thickness direction.

Composition of composition 5 for
forming light absorption anisotropic film

| | |
|---|---|
| Liquid crystalline compound (the FP1) | 3.382 parts by mass |
| Liquid crystalline compound L1 | 3.382 parts by mass |
| The dichroic substance Y1 | 0.370 parts by mass |
| The dichroic substance M1 | 0.089 parts by mass |
| The dichroic substance C1 | 0.665 parts by mass |
| The polymerization initiator I1 | 0.122 parts by mass |
| The interface modifier F2 | 0.003 parts by mass |
| Cyclopentanone | 82.800 parts by mass |
| Tetrahydrofuran | 9.200 parts by mass |

### Examples 24 to 28 and Comparative Example 3

Photo-alignment anisotropic films of Examples 24 to 28 and Comparative Example 3 were manufactured in the same manner as the photo-alignment anisotropic film C of Example 23, except that the liquid crystal composition was changed to a liquid crystal composition having the composition shown in Table 4 below.

[Evaluation]

[Surface Condition]

One linearly polarizer was inserted into each of the light source side and the objective lens side of an optical microscope (product name “ECLIPSE E600⋅POL” manufactured by Nikon Corporation), and arranged to be offset by 90°. The light absorption anisotropic film was set on a sample table, and five places were randomly selected from the light absorption anisotropic film thus set, and observed using a microscope with an objective lens at a magnification of 5 times. An average value of the numbers of defects in the five measured places was calculated, and defect evaluation was performed according to the following evaluation standard. The results are shown in Table 4 below.

A: The average value of numbers of defects is less than 2.

B: The average value of numbers of defects is 2 or more and less than 5.

C: The average value of numbers of defects is 5 or more.

[Reflectance]

A pressure sensitive adhesive (SK-2057, manufactured by Soken Chemical & Engineering Co., Ltd.) was applied to a side opposite to the surface on which each light absorption anisotropic film of Examples and Comparative Examples had been applied, thereby forming a pressure sensitive adhesive layer, and Pure Ace WR (manufactured by Teijin Limited) was bonded thereto. Next, a surface on the Pure Ace WR side was roughened with sandpaper and then treated with a black ink to eliminate backside reflection, and in this state, an adapter ARV-474 was attached to Spectrophotometer V-550 (manufactured by JASCO Corporation), an integrated reflectance at an incidence angle of 5° was measured in a wavelength range of 380 to 780 nm, an average reflectance thereof was calculated, and the antireflection property was evaluated according to the following standard. The results are shown in Table 1 below.

A: The reflectance is 5.9% or less.

B: The reflectance is more than 5.9% and 6.5% or less.

C: The reflectance is more than 6.5%.

TABLE 4

| | Side-chain | | | | | | | | | | | | | | Content | | |
|---|---|---|---|---|---|---|---|---|---|---|---|---|---|---|---|---|---|
| | type | | | | | | | | | | | | | | of side- | | |
| | high- | | | | | | | | | | | | | | chain type | | |
| | molecular- | | | | Dichroic | | | | | | | | Cyclo- | Con- | high- | | |
| | weight liquid | | Other liquid | | substance | | | | | Poly- | | | penta- | tent | molecular- | | |
| | crystalline | | crystalline | | Y1 | M1 | C1 | Surfactant | | merization | | THF | none | of | weight | | |
| | compound | | compounds | | Parts | Parts | Parts | | Parts | initiator | | Parts | Parts | re- | liquid | Align- | Re- |
| | | Parts by | | Parts by | by | by | by | | by | | Parts by | by | by | peating | crystalline | ment | flect- |
| | Type | mass | Type | mass | mass | mass | mass | Type | mass | Type | mass | mass | mass | unit F | compound | degree | ance |
| Example 23 | FP1 | 3.382 | L1 | 3.382 | 0.370 | 0.089 | 0.665 | F3 | 0.003 | I1 | 0.101 | 9.2 | 82.8 | 2.0 | 42.3% by weight | B | A |
| Example 24 | FP2 | 0.128 | L2 | 6.403 | 0.438 | 0.105 | 0.787 | F3 | 0.004 | I1 | 0.120 | 9.2 | 82.8 | 5.0 | 1.6% by weight | B | A |
| Example 25 | FP4 | 1.594 | L2 | 4.942 | 0.436 | 0.104 | 0.784 | F3 | 0.004 | I1 | 0.120 | 9.2 | 82.8 | 5.0 | 19.9% by weight | A | A |
| Example 26 | FP3 | 1.973 | L3 | 4.578 | 0.432 | 0.103 | 0.776 | F3 | 0.004 | I1 | 0.118 | 9.2 | 82.8 | 30.0 | 24.7% by weight | A | A |
| Example | FP5 | 1.815 | L3/ | 2.510/ | 0.432 | 0.103 | 0.776 | F3 | 0.004 | I1 | 0.118 | 9.2 | 82.8 | 30.0 | 22.7% | A | A |
| 27 | | | LM1 | 0.628 | | | | | | | | | | | by weight | | |
| Example 28 | FP5 | 1.788 | L3 | 4.844 | 0.408 | 0.098 | 0.732 | F3 | 0.004 | I1 | 0.112 | 9.2 | 82.8 | 30.0 | 22.4% by weight | A | A |
| Com- | — | — | L1/ | 3.350/ | 0.386 | 0.092 | 0.694 | F3 | 0.004 | I1 | 0.106 | 9.2 | 82.8 | 30.0 | 0.0% | C | C |
| parative | | | LM1 | 3.350 | | | | | | | | | | | by weight | | |
| Exam- | | | | | | | | | | | | | | | | | |
| ple 3 | | | | | | | | | | | | | | | | | |

From the results shown in Table 4 above, it was found that in a case where a side-chain type high-molecular-weight liquid crystalline compound having the repeating unit M including a mesogenic group and the repeating unit F including a fluorine atom is blended, the surface condition is improved even with the high-molecular-weight liquid crystalline compound and the dichroic substance being obliquely aligned, and the reflectance is decreased (Examples 23 to 28).

Furthermore, in Examples 23 to 28, a difference (Δ log P) between the log P values of the side-chain type high-molecular-weight liquid crystalline compound having the repeating unit M including a mesogenic group and the repeating unit F including a fluorine atom and the liquid crystalline compound was in the range of −3.2 to 2.2.

What is claimed is:

1. A liquid crystal composition comprising:
a side-chain type high-molecular-weight liquid crystalline compound; and
a dichroic substance,
wherein the side-chain type high-molecular-weight liquid crystalline compound is a copolymer having a repeating unit M including a mesogenic group and a repeating unit F including a fluorine atom.

2. The liquid crystal composition according to claim 1,
wherein the repeating unit M is a repeating unit represented by Formula (1), 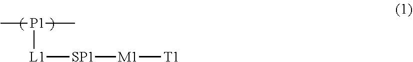
in Formula (1), P1 represents a main chain of the repeating unit, L1 represents a single bond or a divalent linking group, SP1 represents a spacer group, M1 represents a mesogenic group including 2 or more cyclic structures, and T1 represents a terminal group.

3. The liquid crystal composition according to claim 1,
wherein the repeating unit F is a repeating unit represented by Formula (2), 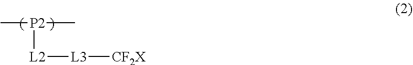
in Formula (2), P2 represents a main chain of the repeating unit, L2 represents a single bond or a divalent linking group, and L3 represents a divalent hydrocarbon group which may have a substituent, provided that one or more of —CH₂-'s constituting the divalent hydrocarbon group may be substituted with —O—, —S—, or —N(Q)-, Q represents a hydrogen atom or a substituent, and X represents a hydrogen atom or a fluorine atom.

4. The liquid crystal composition according to claim 1,
wherein the repeating unit F is repeating unit represented by Formula (3), 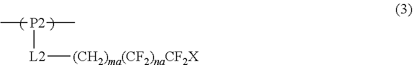
in Formula (3), P2 represents a main chain of the repeating unit, L2 represents a single bond or a divalent linking group, and ma and na each independently represent an integer of 0 to 19, provided that ma and na represent an integer of 0 to 19 in total, and X represents a hydrogen atom or a fluorine atom.

5. The liquid crystal composition according to claim 1,
wherein a content of the repeating unit F is 50% by mass or less with respect to a total mass of the side-chain type high-molecular-weight liquid crystalline compound.

6. The liquid crystal composition according to claim 1,
wherein a content of the side-chain type high-molecular-weight liquid crystalline compound is 0.5% by mass or more with respect to a total mass of a solid content of the liquid crystal composition.

7. The liquid crystal composition according to claim 1, further comprising a liquid crystalline compound other than the side-chain type high-molecular-weight liquid crystalline compound.

8. A side-chain type high-molecular-weight liquid crystalline compound comprising:
a repeating unit represented by Formula (1); and
a repeating unit represented by Formula (3), 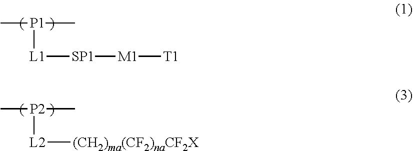
in Formula (1), P1 represents a main chain of the repeating unit, L1 represents a single bond or a divalent linking group, SP1 represents a spacer group, M1 represents a mesogenic group including 2 or more cyclic structures, and T1 represents a terminal group, and
in Formula (3), P2 represents a main chain of the repeating unit, L2 represents a single bond or a divalent linking group, and ma and na each independently represent an integer of 0 to 19, provided that ma and na represent an integer of 0 to 19 in total, and X represents a hydrogen atom or a fluorine atom.

9. A light absorption anisotropic film formed of the liquid crystal composition according to claim 1.

10. A laminate comprising:
a substrate; and
the light absorption anisotropic film according to claim 9 provided on the substrate.

11. The laminate according to claim 10, further comprising a λ/4 plate provided on the light absorption anisotropic film.

12. An image display device comprising the light absorption anisotropic film according to claim 9.

13. An image display device comprising the laminate according to claim 10.

14. The liquid crystal composition according to claim 2,
wherein the repeating unit F is a repeating unit represented by Formula (2), 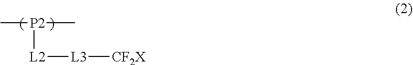
in Formula (2), P2 represents a main chain of the repeating unit, L2 represents a single bond or a divalent linking group, and L3 represents a divalent hydrocarbon group which may have a substituent, provided that one or more of —CH₂-'s constituting the divalent hydrocarbon group may be substituted with —O—, —S—, or —N(Q)-, Q represents a hydrogen atom or a substituent, and X represents a hydrogen atom or a fluorine atom.

15. The liquid crystal composition according to claim 2,
wherein the repeating unit F is a repeating unit represented by Formula (3), 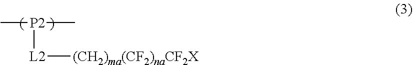
in Formula (3), P2 represents a main chain of the repeating unit, L2 represents a single bond or a divalent linking group, and ma and na each independently represent an integer of 0 to 19, provided that ma and na represent an integer of 0 to 19 in total, and X represents a hydrogen atom or a fluorine atom.

16. The liquid crystal composition according to claim 2,
wherein a content of the repeating unit F is 50% by mass or less with respect to a total mass of the side-chain type high-molecular-weight liquid crystalline compound.

17. The liquid crystal composition according to claim 2,
wherein a content of the side-chain type high-molecular-weight liquid crystalline compound is 0.5% by mass or more with respect to a total mass of a solid content of the liquid crystal composition.

18. The liquid crystal composition according to claim 2, further comprising a liquid crystalline compound other than the side-chain type high-molecular-weight liquid crystalline compound.

19. A light absorption anisotropic film formed of the liquid crystal composition according to claim 2.

20. A laminate comprising:
a substrate; and
the light absorption anisotropic film according to claim 19 provided on the substrate.
